(19) United States
(12) Patent Application Publication
(10) Pub. No.: US 2026/0231616 A1
(43) Pub. Date: Aug. 6, 2026

(54) DISPLAY SUBSTRATE AND PREPARATION METHOD THEREFOR, AND DISPLAY DEVICE

(71) Applicants: Yunnan Invensight Optoelectronics Technology Co., Ltd., Kunming, Yunnan (CN); BOE Technology Group Co., Ltd., Beijing (CN); Beijing BOE Technology Development Co., Ltd., Beijing (CN)

(72) Inventors: Junkai YAN, Beijing (CN); Dongdong SU, Beijing (CN); Yinhu HUANG, Beijing (CN); Bingming FENG, Beijing (CN); Ruquan LI, Beijing (CN); Jixing WANG, Beijing (CN); Jianming ZOU, Beijing (CN); Xiaoyin YANG, Beijing (CN); Xiong YANG, Beijing (CN); Dacheng ZHANG, Beijing (CN)

(21) Appl. No.: 19/151,333

(22) PCT Filed: Jul. 17, 2024
(86) PCT No.: PCT/CN2024/105966

§ 371 Date: Jul. 28, 2025

(30) Foreign Application Priority Data
Aug. 24, 2023 (CN) 202311072456.4

(51) Int. Cl. H10K 59/122; H10K 59/12

(52) U.S. Cl. CPC H10K 59/122; H10K 59/1201

(57) ABSTRACT

A display substrate and a preparation method therefor, and a display device. The display substrate includes a base substrate (200), and a plurality of first electrodes (301) and a plurality of pixel definition structures (302) that are disposed on the base substrate (200), and the pixel definition structures (302) include partition walls (400); the partition walls (400) have one-to-one correspondence to the first electrodes (301), the partition walls (400) are disposed on the outer sides of the first electrodes (301) and surround the first electrodes (301), and adjacent partition walls (400) are spaced apart; each first electrode (301) has a first height (H1), each partition wall (400) has a second height (H2), and the second height (H2) is greater than the first height (H1).

### CROSS-REFERENCE TO RELATED APPLICATION

The present application is a U.S. National Phase Entry of International Application No. PCT/CN2024/105966 having an international filing date of Jul. 17, 2024, which claims priority to Chinese Patent Application No. 202311072456.4, entitled “Display Substrate and Preparation Method therefor, and Display Device”, filed to the CNIPA on Aug. 24, 2023. Contents of the above-identified applications are incorporated into the present application by reference.

### TECHNICAL FIELD

The present disclosure relates to, but is not limited to, a field of display apparatus technology, and particularly to a display substrate and a preparation method therefor, and a display device.

### BACKGROUND

An organic light emitting diode (OLED) and a quantum dot light emitting diode (QLED) are active light emitting display devices and have advantages of self-illumination, a wide viewing angle, a high contrast ratio, low power consumption, an extremely high reaction speed, lightness and thinness, flexibility, and a low cost, etc. With constant development of display technologies, a flexible display device (Flexible Display) in which an OLED or a QLED is used as a light emitting device and signal control is performed through a thin film transistor (TFT) has become a mainstream product in the field of display at present.

At present, existing display substrates have the problem of lateral leakage.

### SUMMARY

The following is a summary of subject matters described herein in detail. This summary is not intended to limit the protection scope of claims.

At least one embodiment of the present disclosure provides a display substrate including a base substrate, and a plurality of first electrodes and a plurality of pixel definition structures disposed on the base substrate, and the pixel definition structures include partition walls. The partition walls are arranged in one-to-one correspondence with the first electrodes, the partition walls are disposed outside the first electrodes and surround the first electrodes, and adjacent partition walls are spaced apart from each other. Each first electrode has a first height and each partition wall has a second height, and the second height is greater than the first height. The first height is configured as a maximum distance between a surface of the first electrode away from the base substrate and a surface of the first electrode close to the base substrate, and the second height is configured as a maximum distance between a surface of the partition wall away from the base substrate and the surface of the first electrode close to the base substrate.

In some exemplary embodiments, a material of the partition wall includes a polymeric material.

In some exemplary embodiments, the material of the partition wall includes a carbon element, an oxygen element, a fluorine element, and a silicon element. A weight percentage of the oxygen element is from 15% to 40%, and a weight percentage of the carbon element is from 20% to 50%.

In some exemplary embodiments, a ratio of the second height to the first height is from 1.5 to 4.0.

In some exemplary embodiments, the partition wall has a first thickness, a ratio of the second height to the first thickness is configured to be greater than 5, and the first thickness is a maximum thickness of the partition wall in a direction parallel to the base substrate.

In some exemplary embodiments, the first thickness is configured to be from 2 nm to 40 nm.

In some exemplary embodiments, in a direction perpendicular to the base substrate, the partition wall includes a first partition portion and a second partition portion. One end of the first partition portion is disposed on the base substrate, the other end of the first partition portion is connected to a first end of the second partition portion, and a second end of the second partition portion extends in a direction away from the base substrate. The first partition portion is bonded to a side wall of the first electrode.

In some exemplary embodiments, the first partition portion has a third height and the second partition portion has a fourth height, and the fourth height is greater than the third height. The third height is a dimension of the first partition portion in the direction perpendicular to the base substrate, and the fourth height is a dimension of the second partition portion in the direction perpendicular to the base substrate.

In some exemplary embodiments, the first partition portion has a second thickness, the second partition portion has a third thickness, and the second thickness is greater than the third thickness. The second thickness is a maximum thickness of the first partition portion in a direction parallel to the base substrate, and the third thickness is a maximum thickness of the second partition portion in the direction parallel to the base substrate.

In some exemplary embodiments, a thickness of the second partition portion gradually decreases along the direction away from the base substrate.

In some exemplary embodiments, the first partition portion has a second thickness, the second partition portion has a third thickness, and the second thickness is less than the third thickness. The second thickness is a maximum thickness of the first partition portion in a direction parallel to the base substrate, and the third thickness is a maximum thickness of the second partition portion in the direction parallel to the base substrate.

In some exemplary embodiments, a thickness of the first partition portion gradually increases along the direction away from the base substrate.

In some exemplary embodiments, the pixel definition structures further include a protection layer disposed at least on a side of the first electrode away from the base substrate and on the partition wall, and the protection layer is provided with a pixel opening exposing the first electrode.

In some exemplary embodiments, the protection layer includes at least a first protection layer and a second protection layer that are stacked, and materials of the first protection layer and the second protection layer include an inorganic material, A strain hardening index of the second protection layer is greater than a strain hardening index of the first protection layer, and the strain hardening index of the first protection layer is greater than a strain hardening index of the partition wall.

In some exemplary embodiments, the first protection layer has a first refractive index, the second protection layer has a second refractive index, and the partition wall has a third refractive index. A ratio of the second refractive index to the first refractive index is from 1.1 to 1.2, and a ratio of the first refractive index to the third refractive index is from 1.1 to 1.2.

In some exemplary embodiments, the partition wall has a first thickness, the first protection layer has a fourth thickness, and the second protection layer has a fifth thickness. A ratio of the fourth thickness to the fifth thickness is from 0.5 to 2, and a ratio of the fourth thickness to the first thickness is from 1 to 10. The first thickness is a maximum thickness of the partition wall in a direction parallel to the base substrate, the fourth thickness is an average thickness of the first protection layer in a direction perpendicular to the base substrate, and the fifth thickness is an average thickness of the second protection layer in the direction perpendicular to the base substrate.

In some exemplary embodiments, in a direction parallel to the base substrate, the protection layer includes at least a partition protection portion disposed on a side of the partition wall away from the base substrate and an electrode protection portion disposed on a side of the first electrode away from the base substrate, and the electrode protection portion is provided with the pixel opening exposing the first electrode.

In some exemplary embodiments, a sidewall of the pixel opening has a stepped structure.

In some exemplary embodiments, the pixel opening includes a first opening provided on the first protection layer and a second opening provided on the second protection layer. The first opening and the second opening are in communication with each other, and an orthographic projection of the first opening on the base substrate is within a range of an orthographic projection of the second opening on the base substrate.

In some exemplary embodiments, the surface of the first electrode away from the base substrate is provided with a first groove, and an orthographic projection of the first groove on the base substrate overlaps with the orthographic projection of the first opening on the base substrate.

In some exemplary embodiments, the partition wall further includes an extension portion located at the surface of the first electrode away from the base substrate, and an orthographic projection of the extension portion on the base substrate overlaps with an orthographic projection of the first electrode on the base substrate. The surface of the first electrode away from the base substrate includes a step surface located at an outer periphery of the first groove, and along a direction away from the base substrate, the step surface includes a seventh end face, a sixth end face, and a fifth end face that are sequentially connected. The fifth end face is located on a side of the seventh end face close to the partition wall, the fifth end face and the seventh end face are both parallel to the base substrate, and the extension portion covers the fifth end face. A distance between the fifth end face and the seventh end face in a direction perpendicular to the base substrate is greater than a groove depth of the first groove.

At least one embodiment of the present disclosure provides a display device including the display substrate described above.

At least one embodiment of the present disclosure further provides a preparation method for a display substrate, including: forming a plurality of first electrodes and a plurality of pixel definition structures on a base substrate. The pixel definition structures include partition walls, the partition walls are arranged in one-to-one correspondence with the first electrodes, the partition walls are disposed outside the first electrodes and surround the first electrodes, and adjacent partition walls are spaced apart from each other. Each first electrode has a first height, each partition wall has a second height, and the second height is greater than the first height. The first height is configured as a maximum distance between a surface of the first electrode away from the base substrate and a surface of the first electrode close to the base substrate, and the second height is configured as a maximum distance between a surface of the partition wall away from the base substrate and the surface of the first electrode close to the base substrate.

In some exemplary embodiments, forming the plurality of first electrodes and the plurality of pixel definition structures on the base substrate includes: forming a composite film layer on the base substrate, coating a photoresist on the composite film layer, and exposing and developing the photoresist to obtain a photoresist pattern; and etching the composite film layer with an etching gas. The etching gas reacts with the photoresist to form polymer particles, the first electrodes are formed after etching the composite film layer, and the polymer particles in aggregate to form the partition walls. The present disclosure provides a display substrate, a preparation method therefor, and a display device. By providing a pixel definition structure including partition walls and protection layers, it is possible to not only solve the problem that the existing display substrate has lateral leakage, but not also increase the pixel aperture ratio and improve the resolution.

Other aspects of the present disclosure may be comprehended after the drawings and the detailed descriptions are read and understood.

### BRIEF DESCRIPTION OF DRAWINGS

FIG. 1 is a schematic diagram of a structure of a display device;

FIG. 2 is a schematic diagram of a planar structure of a silicon-based OLED display device;

FIG. 3 is a schematic diagram of a cross-sectional structure of a silicon-based OLED display device;

FIG. 4 is an equivalent circuit diagram of a pixel drive circuit;

FIG. 5 is a schematic diagram of a structure of a display substrate;

FIG. 6 is a schematic diagram of a display substrate according to an exemplary embodiment of the present disclosure;

FIG. 7 is a first photoresist pattern according to an exemplary embodiment of the present disclosure;

FIG. 8 is a schematic diagram of a structure of a composite film layer according to an exemplary embodiment of the present disclosure;

FIG. 9 is a schematic diagram of a pattern of first electrodes and partition walls according to an exemplary embodiment of the present disclosure;

FIG. 10 is a schematic diagram of a first etching according to an exemplary embodiment of the present disclosure;

FIG. 11 is a schematic diagram of a second etching according to an exemplary embodiment of the present disclosure;

FIG. 12 is a schematic diagram of a third etching according to an exemplary embodiment of the present disclosure;

FIG. 13 is a cross-sectional schematic diagram of a first electrode according to an exemplary embodiment of the present disclosure;

FIG. 14 is a schematic diagram of a planar structure of a first electrode according to an exemplary embodiment of the present disclosure;

FIG. 15 is an axonometric view of a structure of a partition wall according to an exemplary embodiment of the present disclosure;

FIG. 16 is a schematic diagram of a structure of a partition wall and a first electrode according to an exemplary embodiment of the present disclosure;

FIG. 17 is a schematic diagram of a structure of a partition wall and a first electrode according to another exemplary embodiment of the present disclosure;

FIG. 18 is a schematic diagram of a structure of a partition wall and a first electrode according to yet another exemplary embodiment of the present disclosure;

FIG. 19 is a schematic diagram of a structure of a partition wall and a first electrode according to yet another exemplary embodiment of the present disclosure;

FIG. 20 is a schematic diagram of a protection thin film deposition structure according to an exemplary embodiment of the present disclosure;

FIG. 21 is a schematic diagram of a second photoresist pattern according to an exemplary embodiment of the present disclosure;

FIG. 22 is a schematic diagram of a protection layer pattern according to an exemplary embodiment of the present disclosure;

FIG. 23 is a partial schematic view of FIG. 22;

FIG. 24 is another partial schematic view of FIG. 22;

FIG. 25 is a schematic diagram of a display substrate according to yet another exemplary embodiment of the present example;

FIG. 26 is a schematic diagram of a display substrate according to another exemplary embodiment of the present example;

FIG. 27 is a partially enlarged schematic view at A in FIG. 26;

FIG. 28 is a schematic diagram of a display substrate according to yet another exemplary embodiment of the present example;

FIG. 29 is a partially enlarged schematic view at B in FIG. 28;

FIG. 30 is a schematic diagram of a display substrate according to another exemplary embodiment of the present example; and

FIG. 31 is a schematic diagram of a display substrate according to yet another exemplary embodiment of the present example.

Reference signs are described as follows.

| | | |
|---|---|---|
| 101-silicon substrate; | 102-drive circuit layer; | 103-light emitting structure layer; |
| 104-first encapsulation layer; | 105-color film structure layer; | 106-second encapsulation layer; |
| 107-cover plate layer; | 200-base substrate; | 301-first electrode; |
| 302-pixel definition layer; | 303-pixel opening. | 304-groove; |
| 305-organic light emitting layer; | 306-second electrode; | 400-partition wall; |
| 401-first gap; | 402-polymer particle; | 403-first partition portion; |
| 404-second partition portion; | 405-inner wall; | 406-outer wall; |
| 500-protection layer; | 501-first protection layer; | 502-second protection layer; |
| 503-first protection thin film; | 504-second protection thin film; | 505-electrode protection portion; |
| 506-partition protection portion; | 507-substrate protection portion; | 508-first opening; |
| 509-second opening; | 600-composite film layer; | 601-first conductive thin film; |
| 602-second conductive thin film; | 603-third conductive thin film; | 604-fourth conductive thin film; |
| 605-fifth conductive thin film; | 701-first conductive layer; | 702-second conductive layer; |
| 703-third conductive layer; | 704-fourth conductive layer; | 705-transparent conductive layer |
| 707-side wall; | 708-first groove; | 800-stepped surface; |
| 801-first end face; | 802-second end face; | 803-third end face; |
| 804-fourth end face; | 407-extension portion; | 709-second groove; |
| 710-seventh end face | 711-sixth end face; | 712-fifth end face; |
| 713-step surface. | | |

### DETAILED DESCRIPTION

Embodiments of the present disclosure will be described in detail hereinafter with reference to the drawings. It is to be noted that the embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagram only, and one implementation of the present disclosure is not limited to shapes, numerical values, or the like shown in the drawings.

Ordinal numerals “first”, “second”, “third” and the like in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first pole may be a drain electrode, and a second pole may be a source electrode. Or, the first pole may be a source electrode, and the second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element with a certain electrical action. The “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, other elements with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulating layer” sometimes.

A triangle, rectangle, trapezoid, pentagon, or hexagon, or the like in the specification is not strictly defined, and it may be an approximate triangle, rectangle, trapezoid, pentagon, or hexagon, or the like. There may be some small deformations caused by tolerance, and there may be a chamfer, an arc edge, deformation, etc.

In an embodiment of the present disclosure, “about” means that a boundary is not strictly limited, and a value within a range of process and measurement error is allowed.

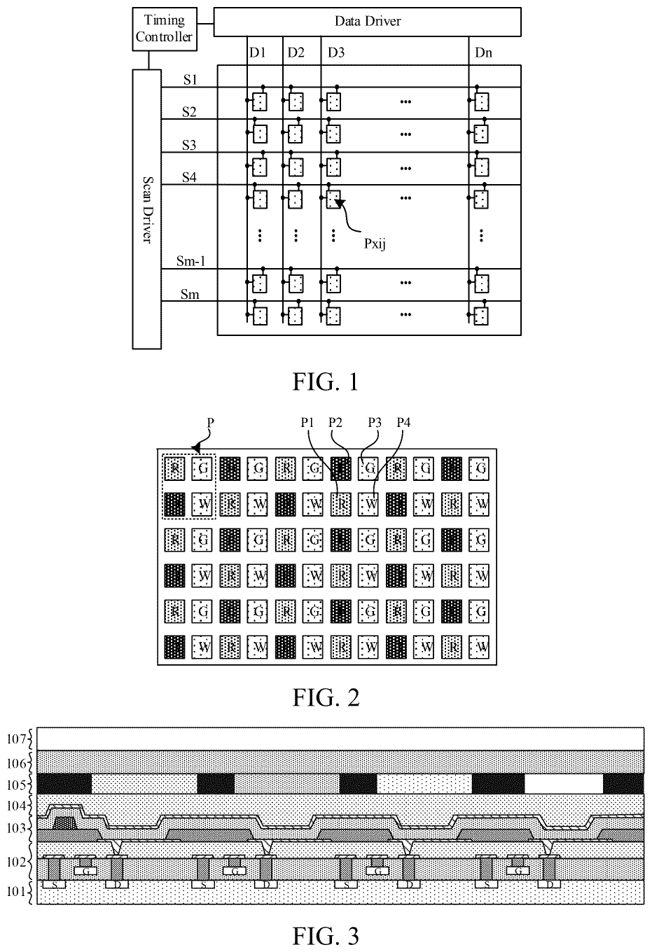

FIG. 1 is a schematic diagram of a structure of a display device. As shown in FIG. 1, an OLED display device may include a timing controller, a data driver, a scan driver and a pixel array. The timing controller is connected with the data driver and the scan driver respectively, the data driver is connected with a plurality of data signal lines (D1 to Dn) respectively, and the scan driver is connected with a plurality of scan signal lines (S1 to Sm) respectively. The pixel array may include a plurality of sub-pixels Pxij. Each sub-pixel Pxij may be connected with a corresponding data signal line and a corresponding scan signal line, wherein i and j may be natural numbers. At least sub-pixel Pxij may at least include a circuit unit and a display unit. The circuit unit may include at least a pixel drive circuit connected with a scan signal line and a data signal line, respectively. The display unit may include at least a light emitting device connected with the pixel drive circuit of the circuit unit, and the sub-pixel Pxij may refer to a sub-pixel in which a pixel drive circuit is connected with an i-th scan signal line and a j-th data signal line. In an exemplary implementation, the timing controller may provide a control signal and a grayscale value suitable for the specification of the data driver to the data driver, and may provide a scan start signal, a clock signal or the like suitable for the specification of the scan driver to the scan driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signal to be provided to the scan signal lines S1, S2, S3, . . . , and Sm by receiving the clock signal and the scan start signal or the like from the timing controller. For example, the scan driver may sequentially provide a scan signal with an on-level pulse to the scan signal lines S1 to Sm. For example, the scan driver may be constructed in a form of a shift register and generate a scan signal in a manner of sequentially transmitting scan start signals provided in a form of an on-level pulse to a next-stage circuit under control of the clock signal, wherein m may be a natural number. In an exemplary implementation, the pixel array may be arranged on a display substrate.

FIG. 2 is a schematic diagram of a planar structure of a silicon-based OLED display device. As shown in FIG. 2, the display device may include a plurality of pixel units P arranged in a matrix, at least one of the plurality of pixel units P include a first sub-pixel P1 emitting light of a first color, a second sub-pixel P2 emitting light of a second color, a third sub-pixel P3 emitting light of a third color, and a fourth sub-pixel P4 emitting light of a fourth color. The four sub-pixels each include a pixel drive circuit and a light emitting device, a pixel drive circuit in a sub-pixel is connected to a scan signal line and a data signal line, respectively, and the pixel drive circuit is configured to receive a data voltage transmitted by the data signal line and output a corresponding current to a light emitting device for display under control of the scan signal line. The light emitting device for display in the sub-pixel is connected to the pixel drive circuit of the sub-pixel where the light emitting device for display is located, and the light emitting device for display is configured to emit light with a corresponding brightness in response to the current outputted by the pixel drive circuit of the sub-pixel where the light emitting device for display is located.

In an exemplary implementation, the first sub-pixel P1 may be a red sub-pixel emitting red (R) light, the second sub-pixel P2 may be a blue sub-pixel emitting blue (B) light, the third sub-pixel P3 may be a green sub-pixel emitting green (G) light, and the fourth sub-pixel P4 may be a white sub-pixel emitting white (W) light. In an exemplary implementation, a shape of the sub-pixels may be any one or more of a triangle, a square, a rectangle, a rhombus, a trapezoid, a parallelogram, a pentagon, a hexagon, and another polygon, and the sub-pixels may be arranged horizontally side by side, vertically side by side, in a shape of an square, or in a diamond shape, etc., which is not limited in the present disclosure.

In an exemplary implementation, the pixel unit may include three sub-pixels, which is not limited in the present disclosure.

FIG. 3 is a schematic diagram of a cross-sectional structure of a silicon-based OLED display device, which illustrates a structure in which full color is implemented in a manner of white light+color film. As shown in FIG. 3, the silicon-based OLED display device may include a silicon substrate 101, a drive circuit layer 102 disposed on the silicon substrate 101, a light emitting structure layer 103 disposed on one side of the drive circuit layer 102 away from the silicon substrate 101, a first encapsulation layer 104 disposed on one side of the light emitting structure layer 103 away from the silicon substrate 101, a color film structure layer 105 disposed on one side of the first encapsulation layer 104 away from the silicon substrate 101, a second encapsulation layer 106 disposed on one side of the color film structure layer 105 away from the silicon substrate 101, and a cover plate layer 107 disposed on one side of the second encapsulation layer 106 away from the silicon substrate 101. In some possible implementations, the silicon-based OLED display device may include another film layer, which is not limited here in the present disclosure.

In an exemplary implementation, the silicon substrate 101 may be a bulk silicon substrate or a Silicon-On-Insulator (SOI) substrate. The drive circuit layer 102 may be fabricated on the silicon substrate 101 through a silicon semiconductor process (e.g., a CMOS process). The drive circuit layer 102 may include a plurality of circuit units, a circuit unit may at least include a pixel drive circuit connected to a scan signal line and a data signal line, respectively. The pixel drive circuit may include a plurality of transistors and a storage capacitor. One transistor is shown only in FIG. 3 as an example. The transistor may include a gate electrode G, a first pole S, and a second pole D. The gate electrode G, the first pole S, and the second pole D may respectively be connected to corresponding connection electrodes through vias filled with tungsten metal (i.e., tungsten vias (W-vias)), and may be connected to other electrical structures (e.g., wires) through the connection electrodes.

In an exemplary implementation, the light emitting structure layer 103 may include a plurality of light emitting devices, and a light emitting device may at least include an anode, an organic light emitting layer, and a cathode. The anode may be connected to the second pole D of the transistor through a connection electrode, the organic light emitting layer is connected to the anode, the cathode is connected to the organic light emitting layer, and the cathode is connected to a second power supply line. The organic light emitting layer emits light under drive of the anode and the cathode. In an exemplary implementation, the organic light emitting layer may include an Emitting Layer (EML) and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, for a light emitting device emitting white light, organic light emitting layers of all sub-pixels may be connected together to be a common layer.

In an exemplary implementation, the first encapsulation layer 104 and the second encapsulation layer 106 may be encapsulated in a manner of Thin Film Encapsulation (TFE), so as to ensure that external water vapor cannot enter the light emitting structure layer. The cover plate layer 107 may be made of glass, or plastic colorless polyimide having flexible characteristics, etc.

In an exemplary implementation, the color film structure layer 105 may include a black matrix (BM) and color filters (CF). The color filters are provided in red sub-pixels, green sub-pixels and blue sub-pixels respectively, and filter white light emitted by the light emitting devices into red (R) light, green (G) light and blue (B) light. The black matrix may be located between adjacent color filters.

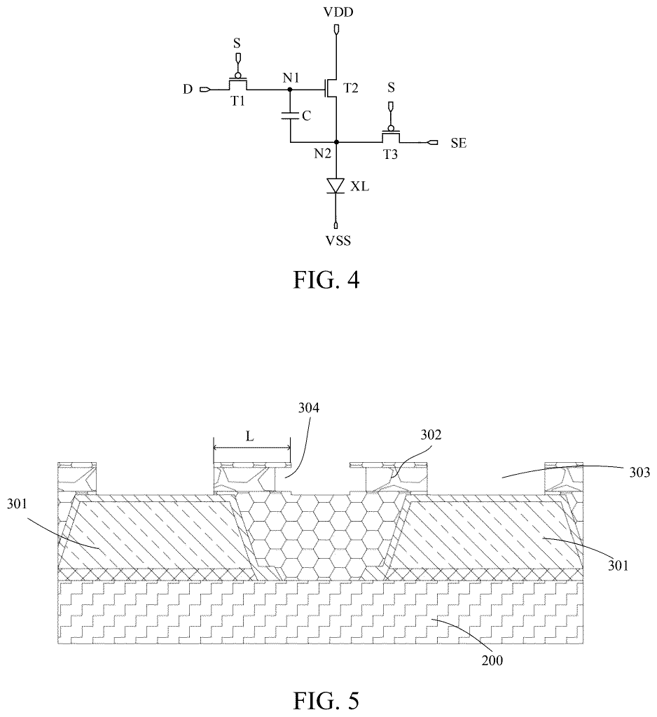

FIG. 4 is an equivalent circuit diagram of a pixel drive circuit. In an exemplary implementation, the pixel drive circuit may be a 3T1C, 4T1C, 5T1C, 5T2C, 6T1C, 7T1C structure or the like. As shown in FIG. 4, the pixel drive circuit may have a 3T1C structure including three transistors (first transistor T1 to third transistor T3) and one storage capacitor C. The pixel drive circuit is connected to four signal lines (scan signal line S, data signal line D, compensation signal line SE, and first power supply line VDD), the first transistor T1 is a switching transistor, the second transistor T2 is a drive transistor, and the third transistor T3 is a compensation transistor.

In an exemplary implementation, each pixel drive circuit may include a first node N1 and a second node N2. The first node N1 is connected with a second pole of the first transistor T1, a gate electrode of the second transistor T2 and a first terminal of the storage capacitor C, respectively, and the second node N2 is connected with a second pole of the second transistor T2, a second pole of the third transistor T3 and a second terminal of the storage capacitor C, respectively.

In an exemplary implementation, the first terminal of the storage capacitor C is connected with the first node N1, the second terminal of the storage capacitor C is connected with the second node N2, and the storage capacitor C is configured to store a potential of the gate electrode of the second transistor T2.

In an exemplary implementation, a gate electrode of the first transistor T1 is connected to the scan signal line S, a first pole of the first transistor T1 is connected to the data signal line D, and the second pole of the first transistor T1 is connected to the first node N1.

In an exemplary implementation, the gate electrode of the second transistor T2 is connected to the first node N1, a first pole of the second transistor T2 is connected to the first power supply line VDD, and the second pole of the second transistor T2 is connected to the second node N2.

In an exemplary implementation, a gate electrode of the third transistor T3 is connected to the scan signal line S, a first pole of the third transistor T3 is connected to the compensation signal line SE, and a second pole of the third transistor T3 is connected to the second node N2.

In an exemplary implementation, a first pole of a light emitting device XL is connected to the second node N2, and a second pole of the light emitting device XL is connected to the second power supply line VSS.

In an exemplary implementation, the light emitting device XL may be an organic electroluminescent light emitting diode (OLED), including a first pole (e.g. anode), an organic light emitting layer and a second pole (e.g. cathode) that are stacked.

In an exemplary implementation, the first transistor T1 is configured to receive a data voltage transmitted by the data signal line D under the control of a signal of the scan signal line S, store the data voltage to the storage capacitor C, and supply the data voltage to the gate electrode of the second transistor T2. The second transistor T2 is configured to generate a corresponding current at the second pole under the control of a data signal received by the gate electrode thereof. The second transistor T2 is configured to supply a signal of the first power supply line VDD to the second node N2 under the control of the third transistor T3 to drive the light emitting device for display XL to emit light. The third transistor T3 is configured to extract a threshold voltage Vth and a mobility of the second transistor T2 in response to compensation timing to compensate the threshold voltage Vth. The storage capacitor C is configured to store a potential of the gate electrode of the second transistor T2. The light emitting device XL is configured to emit light with a corresponding brightness in response to the current of the second pole of the second transistor T2.

In an exemplary implementation, the signal of the first power supply line VDD may be a high-level signal continuously provided, and a signal of the second power supply line VSS may be a low-level signal continuously provided.

In an exemplary implementation, the first transistor T1, the second transistor T2 and the third transistor T3 may be P-type transistors. In another exemplary implementation, the first transistor T1, the second transistor T2, and the third transistor T3 may be N-type transistors. Use of a same type of transistors in a pixel drive circuit may simplify a process flow, reduce a process difficulty of a display panel, and improve a product yield. In yet another exemplary implementation, the first transistor T1, the second transistor T2 and the third transistor T3 may include a P-type transistor and an N-type transistor. For example, the first transistor T1 and the third transistor T3 may be P-type metal oxide semiconductor transistors (PMOS), and the second transistor T2 may be an N-type metal oxide semiconductor transistor (NMOS).

In an exemplary implementation, for the first transistor T1 to the third transistor T3, low temperature poly-silicon thin film transistors may be used, oxide thin film transistors may be used, or a low temperature poly-silicon thin film transistor and an oxide thin film transistor may be used. An active layer of a low temperature poly-silicon thin film transistor is made of Low Temperature Poly-Silicon (LTPS), and an active layer of an oxide thin film transistor is made of an oxide semiconductor (Oxide). The low temperature poly-silicon thin film transistor has advantages, such as a high mobility and fast charging, and the oxide thin film transistor has advantages, such as a low leakage current. The low temperature poly-silicon thin film transistor and the oxide thin film transistor are integrated on one display substrate, that is, an LTPS+Oxide (LTPO) display substrate, so that advantages of the low temperature poly-silicon thin film transistor and the oxide thin film transistor may be utilized, low-frequency drive may be achieved, power consumption may be reduced, and a display quality may be improved.

At present, micro-display products mainly rely on a pixel definition layer (Pixel Design Layer, PDL) to solve the problem of optical crosstalk and lateral leakage between pixels. FIG. 5 is a schematic diagram of a structure of a display substrate, illustrating a structure of a pixel definition layer. As shown in FIG. 5, a main structure of the display substrate includes a base substrate 200, a first electrode 301 and a pixel definition layer 302 and the like. The first electrode 301 is disposed on the base substrate 200, the pixel definition layer 302 is disposed on a side of the first electrode 301 away from the base substrate 200, the pixel definition layer 302 is provided with a pixel opening 303, and the pixel optical crosstalk is prevent by the pixel definition layer 302 blocking light emitted from the light emitting layer. In order to achieve lateral leakage cutoff (LLC), the pixel definition layer 302 is provided with a groove 304, and the groove 304 is configured to reduce a lateral current of a charge generation layer (CGL). Through research by the inventors of the present application, it is found that providing a groove structure on the pixel definition layer 302 did not solve the lateral leakage problem well, and since a distance L between a side wall of the groove 304 and a side wall of the pixel opening 303 in the pixel definition layer 302 is about 300 nm to 500 nm, and the distance L is difficult to reduce, the increase of the pixel aperture ratio and the improvement of the Pixels Per Inch (PPI) are limited.

The present disclosure provides a display substrate including a base substrate, and a plurality of first electrodes and a plurality of pixel definition structures disposed on the base substrate. The pixel definition structures include partition walls, the partition walls are arranged in one-to-one correspondence with the first electrodes, the partition walls are disposed outside the first electrodes and surround the first electrodes, and adjacent partition walls are spaced apart from each other. Each first electrode has a first height, each partition wall has a second height, and the second height is greater than the first height. The first height is configured as a maximum distance between a surface of the first electrode away from the base substrate and a surface of the first electrode close to the base substrate, and the second height is configured as a maximum distance between a surface of the partition wall away from the base substrate and the surface of the first electrode close to the base substrate.

In an exemplary embodiment, a material of the partition wall includes a polymeric material.

In an exemplary embodiment, a ratio of the second height to the first height is from 1.5 to 4.0.

In an exemplary embodiment, the partition wall has a first thickness, a ratio of the second height to the first thickness is configured to be greater than 5, and the first thickness is a maximum thickness of the partition wall in a direction parallel to the base substrate.

In some exemplary embodiments, the pixel definition structure further includes a protection layer disposed at least on a side of the first electrode away from the base substrate and on the partition wall, and the protection layer is provided with a pixel opening exposing the first electrode.

In an exemplary embodiment, the protection layer includes at least a first protection layer and a second protection layer that are stacked, and materials of the first protection layer and the second protection layer include an inorganic material layer. A strain hardening index of the second protection layer is greater than a strain hardening index of the first protection layer, and the strain hardening index of the first protection layer is greater than a strain hardening index of the partition wall.

In an exemplary embodiment, the first protection layer has a first refractive index, the second protection layer has a second refractive index, and the partition wall has a third refractive index. A ratio of the second refractive index to the first refractive index is from 1.1 to 1.2, and a ratio of the first refractive index to the third refractive index is from 1.1 to 1.2.

In an exemplary embodiment, a side wall of the pixel opening has a stepped structure.

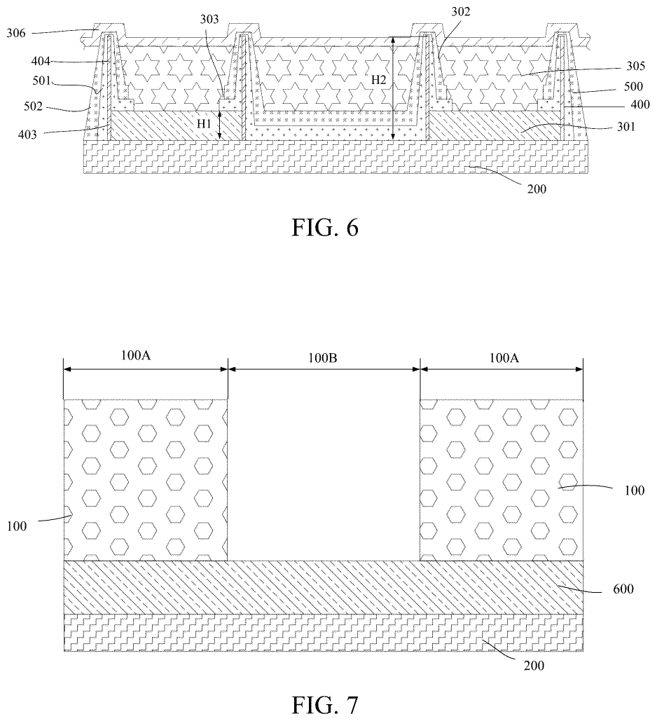

FIG. 6 is a schematic diagram of a display substrate according to an exemplary embodiment of the present disclosure. As shown in FIG. 6, the display substrate may include a base substrate 200, and a plurality of first electrodes 301 and a plurality of pixel definition structures 302 disposed on the base substrate 200, and the pixel definition structures 302 include partition walls 400. The first electrodes 301 may be arranged in one-to-one correspondence with the partition walls 400, the partition walls 400 are disposed outside the first electrodes 301 and surround the first electrodes 301, and adjacent partition walls 400 are spaced apart from each other. Each first electrode 301 has a first height H1, each partition wall 400 has a second height H2, and the second height H2 may be greater than the first height H1. The first height H1 may be a maximum distance between a surface of the first electrode 301 away from the base substrate 200 and a surface of the first electrode 301 close to the base substrate 200, and the second height H2 may be a maximum distance between a surface of the partition wall 400 away from the base substrate 200 and the surface of the first electrode 301 close to the base substrate 200.

In some exemplary embodiments, a ratio of the second height H2 to the first height H1 may be about 1.5 to 4.0.

In some exemplary embodiments, a material of the partition wall 400 may include a polymeric material. The polymeric material may include a carbon element, an oxygen element, a fluorine element, and a silicon element, and a weight percentage of the oxygen element may be from 15% to 40%, and a weight percentage of the carbon element may be from 20% to 50%.

In some exemplary embodiments, the partition wall 400 has a first thickness d1, a ratio of the second height H2 to the first thickness d1 may be greater than 5, and the first thickness d1 is a maximum thickness of the partition wall 400 in a direction parallel to the base substrate 200.

In some exemplary embodiments, in a direction perpendicular to the base substrate 200, the partition wall 400 includes a first partition portion 403 and a second partition portion 404, and the first partition portion 403 may be bonded to a sidewall of the first electrode 301.

In some exemplary embodiments, the first partition portion 403 and the second partition portion 404 may form an integrated structure connected to each other.

In some exemplary embodiments, a protection layer 500 is also included. The protection layer 500 is provided with a pixel opening 303 exposing the first electrode 301 the protection layer 500 may include at least a first protection layer 501 and a second protection layer 502 that are stacked, and the first protection layer 501 and the second protection layer 502 may both include inorganic materials. A strain hardening index of the second protection layer 502 may be greater than a strain hardening index of the first protection layer 501, and the strain hardening index of the first protection layer 501 may be greater than a strain hardening index of the partition wall 400.

In some exemplary embodiments, the first protection layer 501 has a first refractive index, the second protection layer 502 has a second refractive index, and the partition wall 400 has a third refractive index. A ratio of the second refractive index to the first refractive index may be about 1.1 to 1.2, and a ratio of the first refractive index to the third refractive index may be about 1.1 to 1.2.

In some exemplary embodiments, an inner side wall of the pixel opening 303 may have a stepped structure.

In some exemplary embodiments, the display substrate may further include an organic light emitting layer 305 and a second electrode 306. The organic light emitting layer 305 may be disposed on a side of the protection layer 500 away from the base substrate 200, and the organic light emitting layer 305 may be connected to the first electrode 301 through the pixel opening 303. The second electrode 306 may be disposed on a side of the organic light emitting layer 305 away from the base substrate 200, and the second electrode 306 is lapped with the organic light emitting layer 305.

In some exemplary embodiments, in the process of forming the organic light emitting layer 305, the organic light emitting layer 305 is cut off by the partition wall 400. That is, the organic light emitting layer 305 located above the first electrode 301 and the organic light emitting layer 305 located between the adjacent first electrodes 301 are not connected, thus eliminating the lateral current and solving the problem that the existing display substrate has lateral leakage.

In some exemplary embodiments, the second electrode 306 is a whole-surface structure. That is, the second electrode 306 located above the first electrode 301 and the second electrode 306 located between the adjacent first electrodes 301 form an integrated structure connected to each other.

Exemplary description is made below through a preparation process of the display substrate according to the exemplary embodiment. A “patterning process” mentioned in the present disclosure includes treatments such as deposition of a film layer, photoresist coating on a film layer, mask exposure, development, etching, and photoresist stripping for a metal material, an inorganic material, or a transparent conductive material, and includes treatments such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire preparation process, the “thin film” may also be called a “layer”. If the “thin film” need to be processed through the patterning process in the entire preparation process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

In an exemplary implementation, a preparation process of the display substrate may include following operations.

### (1) Forming a Photoresist Pattern.

In some exemplary embodiments, forming a photoresist pattern may include: first forming a composite film layer 600 on a base substrate 200, then coating a photoresist 100 on the composite film layer 600, and exposing and developing the photoresist 100 to obtain a first photoresist pattern, as shown in FIG. 7.

In some exemplary embodiments, the first photoresist pattern may include an exposed region 100A and an unexposed region 100B. The photoresist 100 in the exposed region 100A is retained, the photoresist 100 covers a surface of the composite film layer 600, and the photoresist 100 in the unexposed region 100B is removed, exposing the surface of the composite film layer 600.

In some exemplary embodiments, the exposed region 100A may correspond to a region where the subsequently formed first electrode is located, and the unexposed region 100B may correspond to a spacing region between adjacent first electrodes.

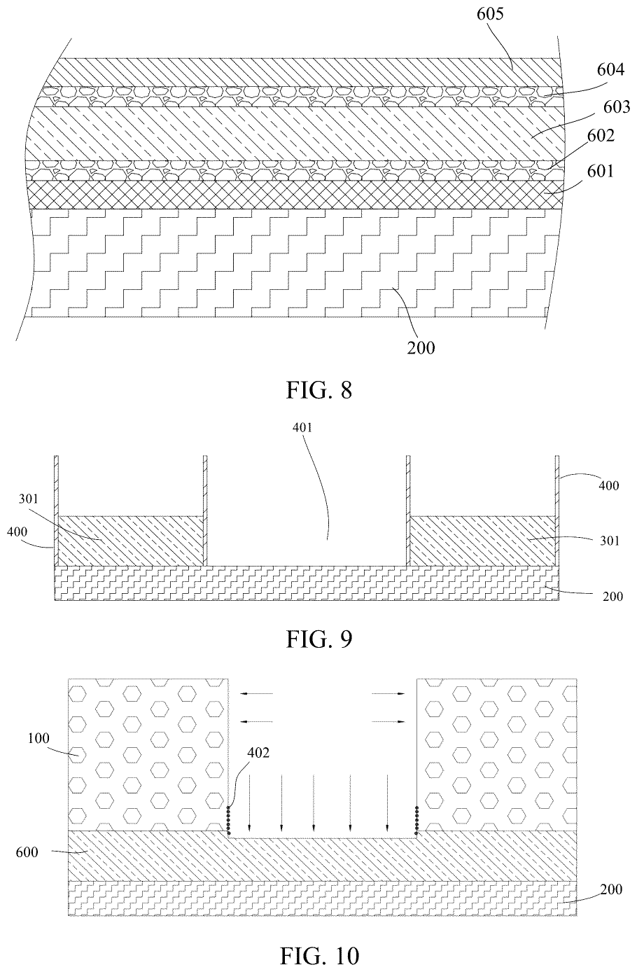

FIG. 8 is a schematic diagram of a structure of a composite film layer according to an exemplary embodiment of the present disclosure. As shown in FIG. 8, in some exemplary embodiments, the composite film layer 600 may include a first conductive thin film 601, a second conductive thin film 602, a third conductive thin film 603, a fourth conductive thin film 604, and a fifth conductive thin film 605 stacked on the base substrate 200. The first conductive thin film 601, the second conductive thin film 602, the third conductive thin film 603, the fourth conductive thin film 604, and the fifth conductive thin film 605 are all conductive materials such as aluminum (Al), titanium (Ti), titanium nitride (TiN), and the like. In some exemplary implementations, the preparation process of the composite film layer 600 may include the following operations. First, a first conductive thin film 601 is deposited on the base substrate 200, and a material of the first conductive thin film 601 may be metal titanium (Ti). Subsequently, a second conductive thin film 602 is deposited on the first conductive thin film 601, and a material of the second conductive thin film 602 may be titanium nitride (TiN). Then, a third conductive thin film 603 is deposited on the second conductive thin film 602, and a material of the third conductive thin film 603 may be metal aluminum (Al). Then, a fourth conductive thin film 604 is deposited on the third conductive thin film 603, and a material of the fourth conductive thin film 604 may be a titanium nitride (TiN) thin film. Then, a fifth conductive thin film 605 is deposited on the fourth conductive thin film 604, and a material of the fifth conductive thin film 605 may be indium tin oxide (ITO). Thus the preparation of the composite film layer 600 is completed.

In some exemplary embodiments, a thickness of the photoresist 100 may be 1200 Å to 2000 Å, and the thickness of the photoresist 100 is a dimension of the photoresist 100 in a direction perpendicular to the base substrate 200. In some exemplary implementations, taking a negative photoresist as an example, the photoresist 100 is coated on the composite film layer 600, initially covering the entire composite film layer 600, and then a mask is used and exposed by ultraviolet light. The light passes through a light transmitting area of the mask and is irradiated onto the photoresist 100 corresponding to the light transmitting area, so that the photoresist 100 corresponding to the light transmitting area is changed. Subsequently, development is performed, and the irradiated photoresist 100 is retained because it is insoluble in the developer, and the non-irradiated photoresist 100 is removed.

### (2) Forming a First Electrode Pattern and a Partition Wall Pattern.

In some exemplary embodiments, forming a first electrode pattern and a partition wall pattern may include: etching the composite film layer 600 by a dry etching process, to form a partition wall pattern while removing the composite film layer 600 in the unexposed region 100B.

In some exemplary embodiments, as shown in FIGS. 7 and 9, the first electrode pattern and the partition wall pattern may include a first electrode 301 and a partition wall 400, and the first electrode 301 and the partition wall 400 are located on one side of the base substrate 200. The partition wall 400 may be a high molecular polymer, the partition wall 400 surrounds the first electrode 301 and is bonded to a side wall of the first electrode 301, and a first gap 401 is formed between the adjacent partition walls 400.

FIGS. 10 to 12 are schematic diagrams of forming a first electrode and a partition wall according to an exemplary embodiment of the present disclosure. In some exemplary embodiments, the etching gas may mainly include chlorine gas (Cl2), boron trichloride (BCl3), carbon tetrafluoride (CF4), and the like. The etching gas can be bombarded into plasma in a chamber of an etching apparatus, and then the etching apparatus will give an electric field to the etching gas as the plasma, to be pulled toward the base substrate 200 to bombard the composite film layer 600. At this time, the larger a bias power parameter of the etching apparatus, the larger a downward traction force and the stronger the bombardment effect. During the downward migration of the plasma etching gas, part of the etching gas will collide with inert molecules such as helium (He) in the chamber, changing the original downward trajectory, thus moving laterally. In the process of etching the composite film layer 600 by the etching gas, the etching gas reacts with the photoresist 100 to form polymer particles 402, and the polymer particles 402 can be accumulated to form the partition wall.

In the etching process, in the process of etching the composite film layer 600 by the etching gas, the etching gas reacts with the photoresist 100 to gradually form the polymer particles 402, and the polymer particles 402 are located in a region of side walls of the photoresist 100 close to the composite film layer 600, as shown in FIG. 10.

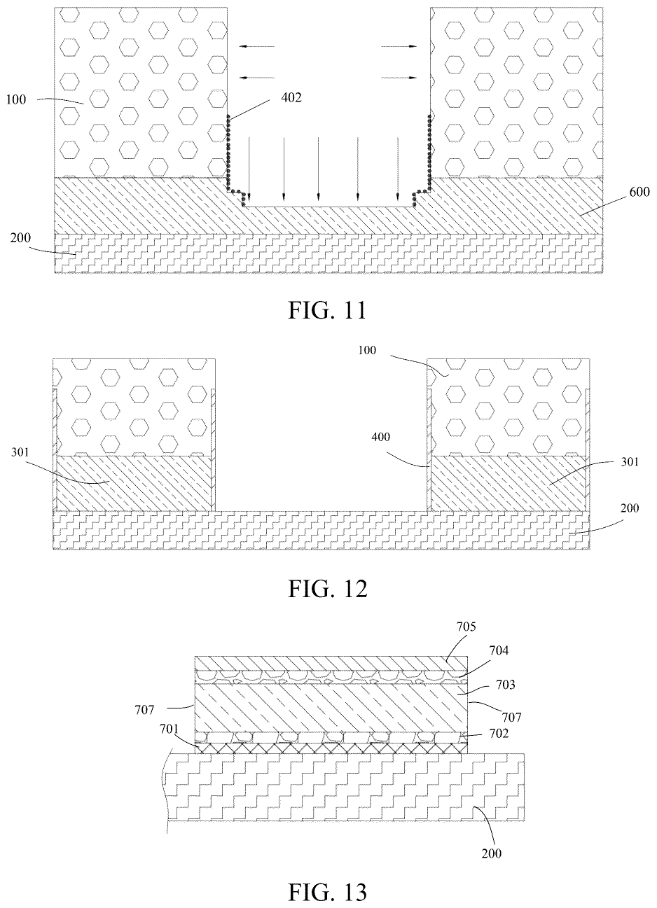

As the composite film layer 600 is continuously etched away and a groove is formed, the number of polymer particles 402 gradually increases, and more polymer particles 402 fall into the groove on the one hand and gather on side walls of the groove, and on the other hand, gather on the side walls of the photoresist 100, as shown in FIG. 11.

When the composite film layer 600 is completely etched away to form the first electrode 301, the polymer particles 402 gathered on the side wall of the first electrode 301 and on the side wall of the photoresist 100 form the partition wall 400. A lower region of the partition wall 400 is bonded to the side wall of the first electrode 301, and an end portion of the partition wall 400 away from the base substrate 200 protrudes from a surface of the first electrode 301 away from the base substrate 200, as shown in FIG. 12.

Subsequently, the photoresist 100 covering the first electrode 30 is stripped off to form the first electrode 301 and the partition wall 400, as shown in FIG. 9.

In some exemplary embodiments, morphology of the partition wall 400 can be adjusted by adjusting etching parameters. The etching parameters may include gas flow volume, pressure, source power, bias power, and the like. The gas flow volume may be a flow volume of gas such as chlorine (Cl2), boron trichloride (BCl3), carbon tetrafluoride (CF4), argon (Ar), and the like. The pressure may be a magnitude of a pressure in a cavity of the etching apparatus. The adjustment of the source power can change the amount of plasma in the cavity of the etching apparatus. The adjustment of the bias power can change a magnitude of the traction force of the plasma etching gas.

In some exemplary embodiments, the formed first electrode 301 includes a first conductive layer, a second conductive layer, a third conductive layer, a fourth conductive layer, and a transparent conductive layer that are stacked in sequence. The first conductive layer may be disposed on the base substrate 200, the first conductive layer is formed by the etching process applied to the first conductive thin film 601, and a material of the first conductive layer may be metal titanium (Ti). The second conductive layer may be disposed on a side of the first conductive layer away from the base substrate 200, the second conductive layer is formed by the etching process applied to the second conductive thin film 602, and a material of the second conductive layer may be titanium nitride (TiN). The third conductive layer may be disposed on a side of the second conductive layer away from the base substrate 200, the third conductive layer is formed by the etching process applied to the third conductive thin film 603, and a material of the third conductive layer may be metal aluminum (Al). The fourth conductive layer may be disposed on a side of the third conductive layer away from the base substrate 200, the fourth conductive layer is formed by the etching process applied to the fourth conductive thin film 604, and a material of the fourth conductive layer may be titanium nitride (TiN). The transparent conductive layer may be disposed on a side of the fourth conductive layer away from the base substrate 200, the transparent conductive layer is formed by the etching process applied to the fifth conductive thin film 605, and a material of the transparent conductive layer may be indium tin oxide (ITO).

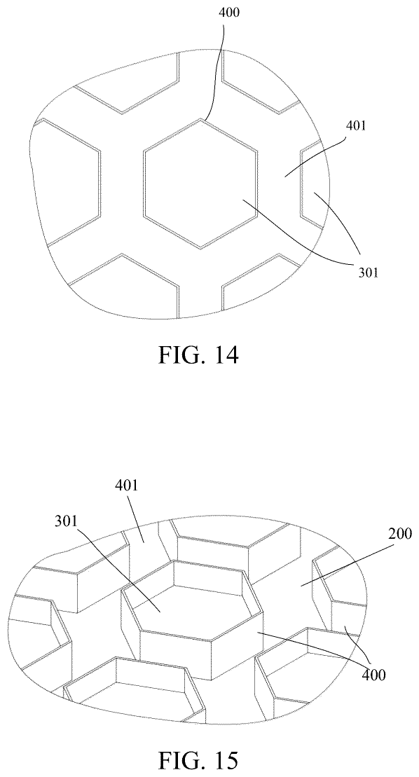

FIG. 13 is a cross-sectional schematic diagram of a first electrode according to an exemplary embodiment of the present disclosure, and FIG. 14 is a schematic diagram of a planar structure of a first electrode according to an exemplary embodiment of the present disclosure. In some exemplary embodiments, as shown in FIGS. 13 and 14, the first electrode 301 may be disposed on the base substrate 200, the first electrode 301 may have a multi-layer stacked structure, the first electrode 30 may include a plurality of conductive film layers parallel to the base substrate 200, and the plurality of conductive film layers may be stacked in a direction perpendicular to the base substrate 200. The number of conductive film layers may be five, and the plurality of conductive film layers include a first conductive layer 701, a second conductive layer 702, a third conductive layer 703, a fourth conductive layer 704, and a transparent conductive layer 705 that are stacked in sequence. The first conductive layer 701 may be disposed on the base substrate 200, and the first conductive layer 701, the second conductive layer 702, the third conductive layer 703, the fourth conductive layer 704, and the transparent conductive layer 705 may be disposed in sequence from the base substrate 200 toward a side away from the base substrate 200. In some exemplary embodiments, the first electrode 301 may adopt a structure of Ti/TiN/Al/TiN/ITO, and a material of the first conductive layer 701 may adopt metal titanium (Ti). The first conductive layer 701 is disposed on the base substrate 200, the first conductive layer 701 is formed by the etching process applied to the first conductive thin film, and a thickness of the first conductive layer 701 may be from 50 nm to 300 nm. A material of the second conductive layer 702 may adopt titanium nitride (TiN), the second conductive layer 702 is disposed on a side of the first conductive layer 701 away from the base substrate 200, the second conductive layer 702 is formed by the etching process applied to the second conductive thin film, and a thickness of the second conductive layer 702 may be from 50 nm to 200 nm. A material of the third conductive layer 703 may adopt metal aluminum (Al), the third conductive layer 703 is disposed on a side of the second conductive layer 702 away from the base substrate 200, the third conductive layer 703 is formed by the etching process applied to the third conductive thin film, and a thickness of the third conductive layer 703 may be from 200 nm to 1000 nm. A material of the fourth conductive layer 704 may adopt titanium nitride (TiN), the fourth conductive layer 704 is disposed on a side of the third conductive layer 703 away from the base substrate 200, the fourth conductive layer 704 is formed by the etching process applied to the fourth conductive thin film, and a thickness of the fourth conductive layer 704 may be from 50 nm to 200 nm. A material of the transparent conductive layer 705 may adopt indium tin oxide (ITO), the transparent conductive layer 705 is disposed on a side of the fourth conductive layer 704 away from the base substrate 200, the transparent conductive layer 705 is formed by the etching process applied to the fifth conductive thin film, and a thickness of the transparent conductive layer 705 may be from 50 nm to 300 nm. As a result, the first electrode 301 contains a metal such as aluminum and titanium, so that the first electrode 301 has a high reflectivity and a work function, which may improve light emitting efficiency. The thicknesses of the first conductive layer 701, the second conductive layer 702, the third conductive layer 703, the fourth conductive layer 704, and the transparent conductive layer 705 described above are dimensions of the respective film layers in a direction perpendicular to the base substrate 200.

In some exemplary embodiments, the first electrode 301 may be an anode or a cathode, and the first electrode 301 is not limited to a five-layer structure, for example, the first electrode 301 may be a three-layer structure.

In some exemplary embodiments, as shown in FIGS. 13 and 14, the first electrode 301 may have a hexagonal structure, a surface of the first electrode 301 facing the base substrate 200 is a bottom wall of the first electrode 301, a surface of the first electrode 301 away from the base substrate 200 is a top wall of the first electrode 301, a surface of the first electrode 301 between the bottom wall and the top wall is a side wall 707 of the first electrode 301, and the side wall 707 is perpendicular to the base substrate 200. The shape of the first electrode 301 is not limited to a hexagonal shape, and the shape of the first electrode 301 can be determined according to the arrangement and shape of the light emitting device.

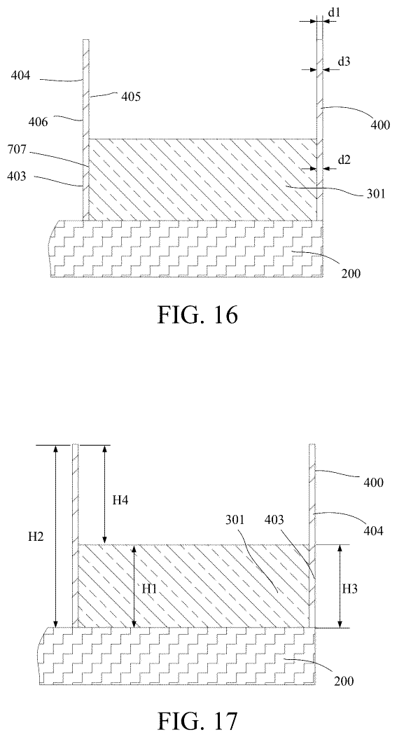

FIG. 15 is an axonometric view of a structure of a partition wall according to an exemplary embodiment of the present disclosure, and FIG. 16 is a cross-sectional view of a partition wall according to an exemplary embodiment of the present disclosure. In some exemplary embodiments, as shown in FIGS. 14, 15, and 16, the partition wall 400 may be perpendicular to the base substrate 200, one end of the partition wall 400 is located on the base substrate 200, and the other end of the partition wall 400 extends away from the base substrate 200 in a direction perpendicular to the base substrate 200, so that an orthographic projection of the partition wall 400 on the base substrate 200 does not overlap with an orthographic projection of the first electrode 301 on the base substrate 200. In a plane parallel to the base substrate, a cross-sectional shape of the partition wall 400 may be hexagonal, so that the partition wall 400 forms a hexagonal ring shape, and the first electrode 301 may be located within the ring shape formed by the partition wall 400. The cross section of the partition wall 400 is not limited to a hexagonal shape, and can be adjusted according to the light emitting device. One end of the partition wall 400 away from the base substrate 200 protrudes from a surface of the first electrode 301 away from the base substrate 200 in a direction perpendicular to the base substrate 200. The partition walls 400 are arranged in one-to-one correspondence with the first electrodes 301, the partition walls 400 and the first electrodes 301 are arranged on the base substrate 200 according to the pixel arrangement structure, a space between two adjacent partition walls 400 is a first gap 401, and the base substrate 200, the partition wall 400 and the first electrode 301 are integrally combined. In the display substrate, the partition wall 400 blocks the light laterally emitted by the light emitting device to solve the problem of pixel light crosstalk, and at the same time, the partition wall 400 can laterally cut off the charge generation layer in the light emitting structure layer to avoid lateral current and achieve the purpose of lateral leakage cutoff. By reducing the distance of the first gap 401, the number of the first electrodes 301 arranged per unit area on the base substrate 200 can be increased, thereby increasing the number of light emitting devices, improving the resolution, effectively increasing the size of the pixel light emitting region, increasing the pixel aperture ratio, and improving the light emitting effect.

In some exemplary embodiments, as shown in FIG. 16, an inner wall 405 of the partition wall 400 may be a surface of the partition wall 400 facing the first electrode 301, and an outer wall 406 of the partition wall 400 may be a surface of the partition wall 400 away from the first electrode 301. A thickness of the partition wall 400 is a distance between the outer wall 406 and the inner wall 405, the partition wall 400 has a first thickness d1, which is a maximum thickness of the partition wall in a direction parallel to the base substrate 200, and the value of the first thickness d1 may be from 2 nm to 40 nm. In this example, the first thickness d1 has a value of 26 nm. The thickness of the partition wall 400 is between 2 nm and 40 nm, and compared to from 300 nm to 500 nm occupied by the related pixel definition layer 302 as shown in FIG. 5, the partition wall 400 in this example is about 1% to 5% of the space occupied by the existing pixel definition layer structure, and the size of the pixel light emitting region can be effectively increased. A portion of the inner wall 405 of the partition wall 400 can be bonded to the side wall 707 of the first electrode 301, and the partition wall 400 has an excellent protective effect on metals such as aluminum (Al) and titanium (Ti) in the first electrode 301, and can avoid defects such as aluminum corrosion and cathode puncture. The partition wall 400 is bonded to the side wall 707 of the first electrode 301, which also forms the partition wall 400 into a hexagonal structure. The partition wall 400 may adopt a high molecular polymer material, and the high molecular polymer material may be a conventional high molecular polymer product formed by reacting the photoresist with the etching gas after the photoresist is melted during the etching process. The main components of the partition wall 400 are carbon element (C), oxygen element (O), fluorine element (F), silicon element (Si), etc., a weight percentage of oxygen element is about 15% to 40%, and a weight percentage of carbon element is about 20% to 50%.

FIG. 17 is a schematic diagram of a structure of a partition wall and a first electrode according to another exemplary embodiment of the present disclosure. As shown in FIG. 17, a height of the partition wall 400 is a dimension of the partition wall 400 perpendicular to the base substrate 200, and the partition wall 400 has a second height H2. The second height H2 is a maximum height in a direction perpendicular to the base substrate 200, that is, a maximum distance between an end of the partition wall 400 away from the base substrate 200 and the surface of the first electrode 301 close to the base substrate 200. A ratio of the second height H2 to a first height H1 may be from 1.5 to 4.0, and the value of the second height H2 may range from 120 nm to 3000 nm. A height of the first electrode 301 is a dimension in a direction perpendicular to the base substrate 200. The first height H1 is a maximum height in a direction perpendicular to the base substrate 200, that is, the first height H1 is a maximum distance between a surface of the first electrode 301 away from the base substrate 200 and a surface of the first electrode 301 close to the base substrate 200, and the value of the first height H1 may range from 400 nm to 2000 nm. The height at which the partition wall 400 protrudes from the first electrode 301 may be a fourth height H4, where H4=H2−H1. In this example, the fourth height H4 may be 2000 nm, and the partition wall 400 is relatively high, so that the partition wall 400 can be used as a good partition structure, and the charge generation layer (CGL) can be cut off when forming the light emitting structure layer, so as to achieve the purpose of lateral leakage cutoff. In addition, the second height H2 of the partition wall 400 and the fourth height H4 at which the partition wall 400 protrudes from the first electrode 301 can be adjusted according to the display substrate data.

In some exemplary embodiments, as shown in FIGS. 16 and 17, the partition wall 400 has a first thickness d1, and a ratio of the second height H2 to the first thickness d1 may be greater than 5. The first thickness d1 is a maximum thickness of the partition wall 400 in a direction parallel to the base substrate 200. The second height H2 is a maximum distance between an end of the partition wall 400 away from the base substrate 200 and the surface of the first electrode 301 close to the base substrate 200. In this example, the ratio of the second height H2 to the first thickness d1 is greater than 20. A ratio of the dimension of the partition wall 400 in a direction perpendicular to the base substrate 200 to the dimension of the partition wall 400 in a direction parallel to the base substrate 200 is large, forming a structure that is narrow and elongate in a direction perpendicular to the base substrate 200. The pixel definition layer of the present example occupies less space in a direction parallel to the base substrate 200 compared with the related pixel definition layer, but it is not limited thereto. For example, the ratio of the second height H2 to the first thickness d1 is greater than 10, but less than 20, which also occupies less space in a direction parallel to the base substrate 200 compared with the related pixel definition layer.

In some exemplary embodiments, as shown in FIGS. 16 and 17, the partition wall 400 may include two parts in a direction perpendicular to the base substrate 200, that is, a first partition portion 403 and a second partition portion 404. A connection position of the first partition portion 403 and the second partition portion 404 may be located at the surface of the first electrode 301 away from the base substrate 200, and the first partition portion 403 and the second partition portion 404 may be of an integrated member. Both the first partition portion 403 and the second partition portion 404 extend in a direction perpendicular to the base substrate 200, one end of the first partition portion 403 in a direction perpendicular to the base substrate is disposed on the base substrate 200, and the other end of the first partition portion 403 in a direction perpendicular to the base substrate extends to the surface of the first electrode 301 away from the base substrate 200 and is connected to the second partition portion 404. The first partition portion 403 has a third height, and the third height is a dimension of the first partition portion 403 in a direction perpendicular to the base substrate 200. The fourth height may also be a dimension of the second partition portion 404 in a direction perpendicular to the base substrate 200, and the fourth height is greater than the third height. A thickness of the first partition portion 403 may be a distance between an inner wall and an outer wall of the first partition portion 403, and the first partition portion 403 has a second thickness d2 that is a maximum thickness of the first partition portion 403 in a direction parallel to the base substrate 200. A thickness of the second partition portion 404 is a distance between an inner wall and an outer wall of the second partition portion 404, and the second partition portion 404 has a third thickness d3 that is a maximum thickness of the second partition portion 404 in a direction parallel to the base substrate 200. The value of the second thickness d2 may be the same as the value of the third thickness d3, so that the thickness d1 of the partition wall 400 is the same everywhere in a direction perpendicular to the base substrate 200.

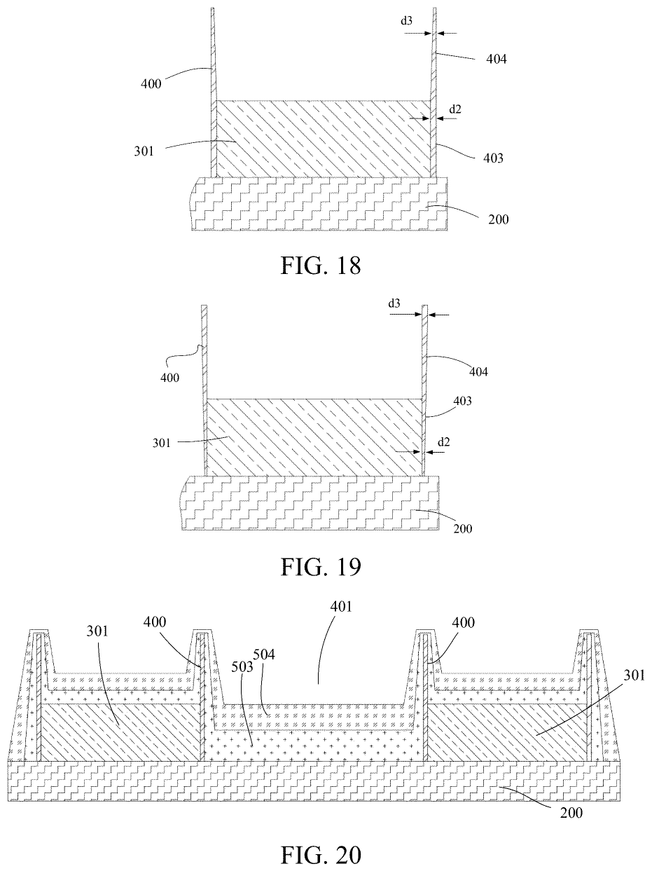

FIG. 18 is a schematic diagram of a structure of a partition wall and a first electrode according to yet another exemplary embodiment of the present disclosure. In some exemplary embodiments, as shown in FIG. 18, the first partition portion 403 has a second thickness d2, and the second partition portion 404 has a third thickness d3. The thicknesses of the first partition portion 403 and the second partition portion 404 at a same height in a circumferential direction of the first electrode 301 are substantially the same. The value of the second thickness d2 may be different from that of the third thickness d3. The value of the second thickness d2 may be from 10 nm to 30 nm, the value of the third thickness d3 may be from 2 nm to 10 nm, and the value of the third thickness d3 is less than that of the second thickness d2. As a result, the thickness of the second partition portion 404 is relatively small, the occupied space in the lateral direction is reduced, and the light emitting area of the pixels in the display area occupied by the partition wall 400 is reduced as much as possible, so as to increase the light emitting area, increase the pixel aperture ratio thereof, and improve the light emitting efficiency. The thickness of the second partition portion 404 may vary in a direction perpendicular to the base substrate 200, and it may gradually decrease from one end connected to the first partition portion 403 to the other end. In this way, the thickness at one end of the second partition portion 404 away from the first partition portion 403 is further reduced, so that the light emitting area can be further increased, and the light emitting efficiency can be improved. The thickness control of the partition wall 400 can be achieved by adjusting the etching parameters during the etching process.

FIG. 19 is a schematic diagram of a structure of a partition wall and a first electrode according to yet another exemplary embodiment of the present disclosure. In some exemplary embodiments, as shown in FIG. 19, the first partition portion 403 has a second thickness d2, and the second partition portion 404 has a third thickness d3. The thicknesses of the first partition portion 403 and the second partition portion 404 at a same height in the circumferential direction of the first electrode 301 are substantially the same, and the value of the second thickness d2 is less than that of the third thickness d3. The partition wall 400 narrows from one end away from the base substrate 200 to the other end in a direction perpendicular to the base substrate 200, and the thickness of the first partition portion 403 is relatively small near the base substrate 200. In this way, the occupied space of the first partition portion 403 is reduced, so that more first electrodes 301 can be arranged on the base substrate 200, and the pixel density can be improved, thus improving the resolution and the light emitting efficiency. The thickness control of the partition wall 400 can be achieved by adjusting the etching parameters during the etching process.

### (3) Forming a Protection Layer Pattern.

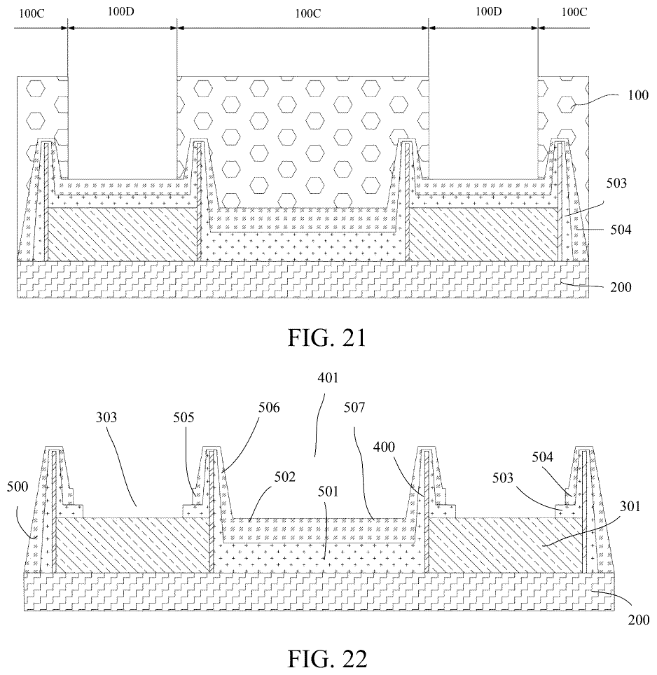

In some exemplary embodiments, forming a protection layer pattern may include: first, sequentially depositing a first protection thin film 503 and a second protection thin film 504 on the base substrate 200 on which the first electrode pattern and the partition wall pattern are formed, as shown in FIG. 21. Subsequently, a layer of photoresist 100 is coated on the second protection thin film 504, and the photoresist 100 is exposed and developed, as shown in FIG. 22. Subsequently, the first protection thin film 503 and the second protection thin film 504 are etched to strip off the remaining photoresist 100 to form a protection layer pattern, as shown in FIG. 22.

In some exemplary embodiments, as shown in FIG. 20, the first protection thin film 503 covers the base substrate 200, the first electrode 301 and the partition wall 400, and the second protection thin film 504 is located on a side of the first protection thin film 503 away from the base substrate 200. In this example, a material of the first protection thin film 503 may be silicon oxide (SiOx), and a material of the second protection thin film 504 may be silicon nitride (SiNx). In some possible exemplary embodiments, the materials of the first protection thin film 503 and the second protection thin film 504 are not limited thereto, and may be other inorganic materials.

Then, the photoresist 100 is covered on the second protection thin film 504, and then exposed and developed to obtain a second photoresist pattern as shown in FIG. 21, and the photoresist pattern may include an exposed region 100C and an unexposed region 100D. The photoresist 100 in the exposed region 100C is retained, and the photoresist 100 covers a surface of the second protection thin film 504 away from the first protection thin film 503. The photoresist 100 in the unexposed region 100D is removed, exposing the surface of the second protection thin film 504 away from the first protection thin film 503.

In some exemplary embodiments, the unexposed region 100D may correspond to a region where the pixel opening is located.

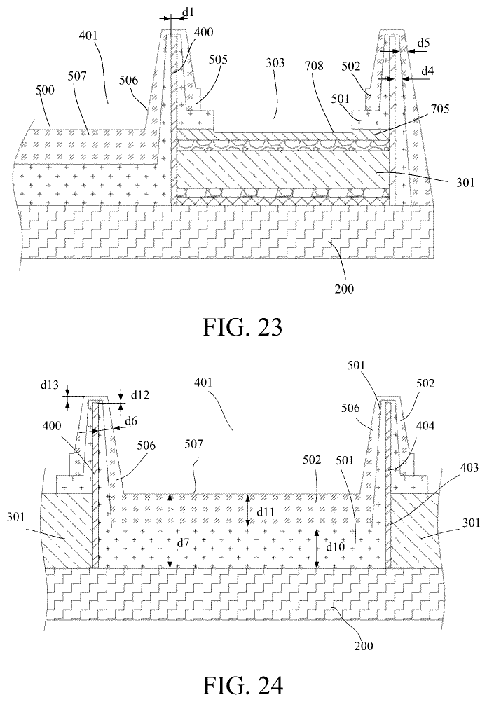

Subsequently, the first protection thin film 503 and the second protection thin film 504 are etched, and the etching process may adopt dry etching. The first protection thin film 503 and the second protection thin film 504 in the unexposed region 100D are etched away to form a protection layer 500 having a pixel opening 303, and a protection layer pattern as shown in FIG. 23 is obtained. The protection layer 500 has a two-layer structure, and the two-layer structure includes a first protection layer 501 and a second protection layer 502. The first protection layer 501 covers the base substrate 200, the first electrode 301, and the partition wall 400. The second protection layer 502 is located on a side of the first protection layer 501 away from the base substrate 200. The protection layer 500 may include an electrode protection portion 505, a partition protection portion 506, and a substrate protection portion 507. The electrode protection portion 505 covers the first electrode 301 and is provided with the pixel opening 303, the partition protection portion 506 covers the partition wall 400, and the substrate protection portion 507 covers the base substrate 200 between two adjacent partition walls 400.

FIG. 22 is a schematic diagram of a protection layer pattern according to an exemplary embodiment of the present disclosure. As shown in FIG. 22, the display substrate may include a protection layer 500, the protection layer 500 covers at least a part of the surface of the partition wall 400, and the protection layer 500 may protect the partition wall 400, avoiding damaging the thin partition wall 400. The protection layer 500 is divided into a substrate protection portion 507, an electrode protection portion 505 and a partition protection portion 506 in a direction parallel to the base substrate 200 according to the position. The substrate protection portion 507 is located in the first gap 401 between two adjacent partition walls 400 and covers the base substrate 200, the partition protection portion 506 is wrapped around the surface of the partition wall 400, and the electrode protection portion 505 covers an edge of the surface of the first electrode 301 away from the base substrate 200 and is provided with the pixel opening 303.

FIG. 23 is a partial schematic view of FIG. 22. In some exemplary embodiments, as shown in FIGS. 22 and 23, the protection layer 500 may be a two-layer structure, and the two-layer structure may include a first protection layer 501 and a second protection layer 502. The first protection layer 501 covers the base substrate 200, the first electrode 301 and the partition wall 400, and the second protection layer 502 is located on a side of the first protection layer 501 away from the base substrate 200. In the present example, the material of the first protection layer 501 may be silicon oxide (SiOx) and the material of the second protection layer 502 may be silicon nitride (SiNx), but it is not limited thereto. The materials of the first protection layer 501 and the second protection layer 502 may be other inorganic materials. Both the first protection layer 501 and the second protection layer 502 are inorganic materials formed by chemical vapor deposition (CVD). The chemical vapor deposition is a method in which chemical gases or vapors react on the surface of the base to synthesize coatings or nanomaterials, and are the most widely used technique in the semiconductor industry for depositing a wide range of materials, including a wide range of insulating materials, most metallic materials and metal alloy materials. The substrate protection portion 507, the electrode protection portion 505, and the partition protection portion 506 described above adopt the same two-layer structure described above. The first protection layer 501 of the substrate protection portion 507 covers the base substrate 200, and the second protection layer 502 of the substrate protection portion 507 is deposited on a side of the first protection layer 501 away from the base substrate 200. The first protection layer 501 of the partition protection portion 506 covers the partition wall 400, and the second protection layer 502 of the partition protection portion 506 is deposited on a side of the first protection layer 501 away from the partition wall 400. The first protection layer 501 of the electrode protection portion 505 covers a surface of the first electrode 301, and the second protection layer 502 of the electrode protection portion 505 is deposited on a side of the first protection layer 501 away from the first electrode 301. The protection layer 500 may be integrated with the partition wall 400 to form a composite structure of SiNx/SiOx/polymer. Refractive indices of the first protection layer 501, the second protection layer 502, and the partition wall 400 are sequentially a first refractive index n1, a second refractive index n2, and a third refractive index n3. A ratio of the second refractive index n2 to the first refractive index n1 is about 1.1 to 1.2, and a ratio of the first refractive index n1 to the third refractive index n3 is about 1.1 to 1.2. Strain hardening indices (material N value) of the second protection layer 502, the first protection layer 501, and the partition wall 400 decrease sequentially, that is, the strain hardening index of the second protection layer 502 is greater than the strain hardening index of the first protection layer 501, and the strain hardening index of the first protection layer 501 is greater than the strain hardening index of the partition wall 400.

In some exemplary embodiments, as shown in FIG. 24, a thickness of the first protection layer 501 is a distance from a surface of the first protection layer 501 close to the second protection layer 502 to a surface of the first protection layer 501 away from the second protection layer 502. The first protection layer 501 has a fourth thickness d4, which is an average thickness of the first protection layer 501 in a direction perpendicular to the base substrate 200. A thickness of the second protection layer 502 is a distance from a surface of the second protection layer 502 close to the first protection layer 501 to a surface of the second protection layer 502 away from the first protection layer 501. The second protection layer 502 has a fifth thickness d5, which is an average thickness of the second protection layer 502 in a direction perpendicular to the base substrate 200. The partition wall 400 has the first thickness d1 described above, a ratio of the fourth thickness d4 to the fifth thickness d5 may be about 0.5 to 2, and a ratio of the fourth thickness d4 to the first thickness d1 may be about 1 to 10.

FIG. 24 is another partial schematic view of FIG. 22. In some exemplary embodiments, as shown in FIG. 24, the substrate protection portion 507 covers the surface of the base substrate 200 in the first gap 401, and the substrate protection portion 507 is located between two adjacent partition walls 400 and connects the partition protection portions 506 on the two adjacent partition walls 400. A thickness of the substrate protection portion 507 may be a distance between an end face of the substrate protection portion 507 away from the base substrate 200 and an end face of the substrate protection portion 507 close to the base substrate 200. The substrate protection portion 507 has a seventh thickness d7, which is an average thickness in a direction perpendicular to the base substrate 200, and the value of the seventh thickness d7 may be from 70 nm to 140 nm. A thickness of the second protection layer 502 of the substrate protection portion 507 may be a distance between an end face of the second protection layer 502 of the substrate protection portion 507 away from the base substrate 200 and an end face of the second protection layer 502 of the substrate protection portion 507 close to the base substrate 200. The second protection layer 502 of the substrate protection portion 507 has an eleventh thickness d11, which is an average thickness of the second protection layer 502 of the substrate protection portion 507 in a direction perpendicular to the base substrate 200, and the value of the eleventh thickness d11 may be from 30 nm to 60 nm. A thickness of the first protection layer 501 of the substrate protection portion 507 may be a distance between an end face of the first protection layer 501 of the substrate protection portion 507 away from the base substrate 200 and an end face of the first protection layer 501 of the substrate protection portion 507 close to the base substrate 200. The first protection layer 501 of the substrate protection portion 507 has a tenth thickness d10, which is an average thickness of the first protection layer 501 of the substrate protection portion 507 in a direction perpendicular to the base substrate 200, and the value of the tenth thickness d10 may be from 40 nm to 80 nm. The relatively large thickness value of the substrate protection portion 507 can appropriately increase the height of a gap region between pixels, thereby further avoiding defects such as cathode puncture caused by contact between the organic light emitting layer of the evaporation material and the first electrode 301.

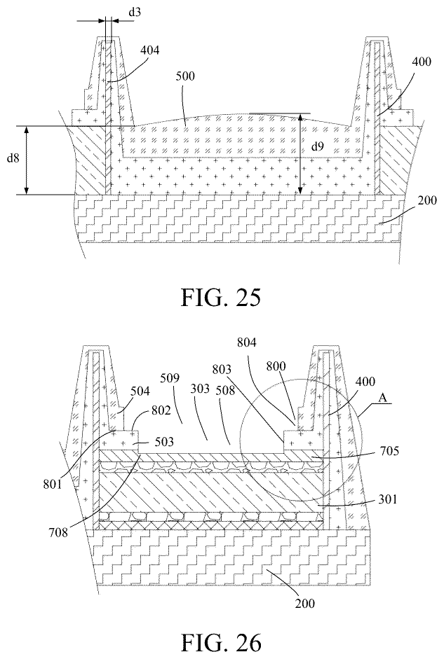

FIG. 25 is a schematic diagram of a display substrate according to yet another exemplary embodiment of the present example. In some exemplary embodiments, as shown in FIG. 25, the second partition portion 404 has a third thickness d3, a thickness of the base substrate protection 507 at a position close to the partition wall 400 may be an eighth thickness d8, and a thickness of the base substrate protection 507 at a position away from the partition wall 400 may be a ninth thickness d9. The value of the eighth thickness d8 is less than the value of the ninth thickness d9, resulting in a situation where the base substrate protection 507 is thick in the middle and thin at the edges. The structure of the substrate protection portion 507 that is thick in the middle and thin at the edges is caused by the formation of shadow in the evaporation process, and it is possible to avoid the situation of thick in the middle and thin at the edges by using surface source evaporation. Further, a difference between the eighth thickness d8 and the ninth thickness d9 may be less than the third thickness d3 of the second partition portion 404, that is, |d8−d9|<d3.

In some exemplary embodiments, as shown in FIG. 24, the partition protection portion 506 covers a surface of the second partition portion 404 of the partition wall 400 and a surface of the first partition portion 403 of the partition wall 400 away from the first electrode 301. A thickness of the partition protection portion 506 may be a distance between an end face of the partition protection portion 506 close to the partition wall 400 and an end face of the partition protection portion 506 away from the partition wall 400. A thickness of the partition protection portion 506 may be a sixth thickness d6, which is linearly decreased from the base substrate 200 towards the side away from the base substrate 200, so that the thickness of the partition protection portion 506 on the side away from the base substrate 200 is relatively thin. The thickness of the partition protection portion 506 is a distance from a surface of the partition protection portion 506 close to the partition wall 400 to a surface of the partition protection portion 506 away from the partition wall 400. A thickness of the first protection layer 501 of the partition protection portion 506 may be a distance between an end face of the first protection layer 501 of the partition protection portion 506 close to the partition wall 400 and an end face of the first protection layer 501 of the partition protection portion 506 away from the partition wall 400. On a side away from the base substrate 200, a thickness of the first protection layer 501 of the partition protection portion 506 may be a twelfth thickness d12, and the value of the twelfth thickness d12 may range from 30 nm to 50 nm. A thickness of the second protection layer 502 of the partition protection portion 506 may be a distance between an end face of the second protection layer 502 of the partition protection portion 506 close to the partition wall 400 and an end face of the second protection layer 502 of the partition protection portion 506 away from the partition wall 400. The thickness of the second protection layer 502 of the partition protection portion 506 may be a thirteenth thickness d13, and the value of the thirteenth thickness d13 may be range from 20 nm to 40 nm. As a result, the partition protection portion 506 has a relatively small thickness at its end away from the base substrate 200 to enlarge the opening, so that more light can be emitted, the light emitting area is enlarged, light scattering is reduced and light emitting efficiency is improved. The structure of the partition protection portion 506 is not limited thereto, for example, the thickness of the partition protection portion 506 remains substantially uniform throughout the direction perpendicular to the base substrate 200.

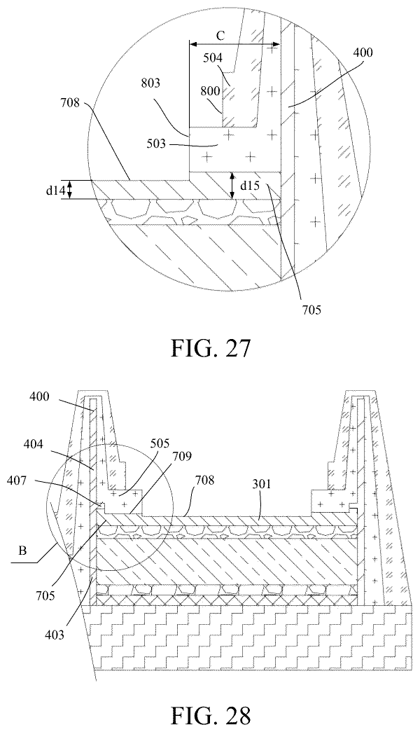

FIG. 26 is a schematic diagram of a display substrate according to another exemplary embodiment of the present example, and FIG. 27 is a partially enlarged schematic view at A in FIG. 26. In some exemplary embodiments, as shown in FIGS. 26 and 27, the electrode protection portion 505 covers a portion of the surface of the first electrode 301 away from the base substrate 200, and the electrode protection portion 505 may form a hexagonal ring shape along the inner wall of the partition wall 400, so as to form a pixel opening 303 that exposes the first electrode 301. The pixel opening 303 is centrally disposed with respect to the first electrode 301, and the pixel opening 303 includes a first opening 508 and a second opening 509. The first opening 508 is formed by the first protection layer 501 of the electrode protection portion 505, and the second opening 509 is formed by the second protection layer 502 of the electrode protection portion 505. The first opening 508 and the second opening 509 are both centrally disposed with respect to the first electrode 301. The first opening 508 penetrates the first protection layer 501 of the electrode protection portion 505, and the second opening 509 penetrates the second protection layer 502 of the electrode protection portion 505. One end of the first opening 508 away from the first electrode 301 is in communication with the second opening 509. Opening sizes of the first opening 508 and the second opening 509 are different. The opening size of the first opening 508 is less than the opening size of the second opening 509, so that the inner side wall of the pixel opening 303 forms a stepped surface 800, and an orthographic projection of the first opening 508 on the base substrate 200 is within a range of an orthographic projection of the second opening 509 on the base substrate 200. At the stepped surface 800, end faces of the first protection layer 501 and the second protection layer 502 of the electrode protection portion 505 are arranged in a staggered manner. The first protection layer 501 of the electrode protection portion 505 is parallel to the base substrate 200, an end face of the first protection layer 501 away from the first electrode 301 includes a first end face 801 and a second end face 802 that are connected with each other, and the second end face 802 is disposed on a side of the first end face 801 away from the partition wall 400. The first end face 801 is covered by the second protection layer 502 of the electrode protection portion 505, and the second protection layer 502 of the electrode protection portion 505 extends from one end close to the partition wall 400 to the connection of the first end face 801 and the second end face 802. The second end face 802 is exposed and not covered by the second protection layer 502 of the electrode protection portion 505. An end face of the first protection layer 501 of the electrode protection portion 505 away from the partition wall 400 may be a third end face 803, and an end face of the second protection layer 502 of the electrode protection portion 505 away from the partition wall 400 may be a fourth end face 804. The third end face 803 and the fourth end face 804 are staggered in a direction parallel to the base substrate 200, and the third end face 803, the second end face 802, and the fourth end face 804 constitute the stepped surface 800.

In some exemplary embodiments, as shown in FIGS. 27 and 28, the electrode protection portion 505 covers an edge of the transparent conductive layer 705 of the first electrode 301 away from the end face, a length of the third end face 803 of the electrode protection portion 505 to the partition wall 400 is a first distance (C), and the value of the first distance (C) may be from 2 nm to 20 nm. A surface of the transparent conductive layer 705 of the first electrode 301 away from the base substrate 200 may be provided with a first groove 708, and the first groove 708 corresponds to the first opening 508 in a direction perpendicular to the base substrate 200. The electrode protection portion 505 may be disposed on the end face of the transparent conductive layer 705 away from the end face of the base substrate 200 and at the outer periphery of the first groove 708, so that the first groove 708 is not covered by the electrode protection portion 505. A groove sidewall of the first groove 708 may be flush with the third end face 803 of the electrode protection portion 505, and the end face flush structure is formed by etching during processing such that an orthographic projection of the first groove 708 on the base substrate 200 overlaps with an orthographic projection of the first opening 508 on the base substrate 200. The transparent conductive layer 705 of the first electrode 301 has the first groove 708, a thickness of the transparent conductive layer 705 of the first electrode 30 at the first groove 708 may be a fourteenth thickness d14, and the fourteenth thickness d14 is relatively thin. A thickness of the transparent conductive layer 705 of the first electrode 301 at a peripheral edge of the first groove 708 may be a fifteenth thickness d15, and the fifteenth thickness d15 is relatively thick. The value of the fifteenth thickness d15 is greater than the value of the fourteenth thickness d14.

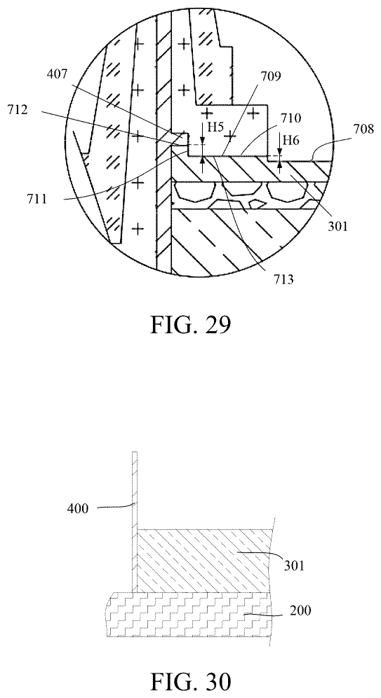

FIG. 28 is a schematic diagram of a display substrate according to yet another exemplary embodiment of the present example, and FIG. 29 is a partially enlarged schematic view at B in FIG. 28. In some exemplary embodiments, as shown in FIGS. 28 and 29, an orthographic projection of the partition wall 400 on the base substrate 200 overlaps with an orthographic projection of the first electrode 301 on the base substrate 200. In addition to the first partition portion 403 and the second partition portion 404, the partition wall 400 may further include an extension portion 407 at the connection of the first partition portion 403 and the second partition portion 404 and on a side of the partition wall 400 close to the first electrode 301. The extension portion 407 is bonded to the surface of the first electrode 301 away from the base substrate 200, and an orthographic projection of the extension portion 407 on the base substrate 200 may be within the orthographic projection of the first electrode 301 on the base substrate 200. The extension portion 407 can be integrally formed with the first partition portion 403 and the second partition portion 404, and is formed of polymer particles with a long etching time. During the etching process, the polymer particles formed by the reaction of the photoresist will also grow along the surface of the first electrode 301 away from the base substrate 200 to form the extension portion 407.

In some exemplary embodiments, as shown in FIGS. 28 and 29, the surface of the first electrode 301 away from the base substrate 200 is provided with a second groove 709. A portion the surface of the first electrode 301 away from the base substrate 200 at the outer periphery of the second groove 709 is a fifth end face 712, a sixth end face 711 constitutes a groove side wall of the second groove 709, a seventh end face 710 constitutes a groove bottom wall of the second groove 709, and the above-mentioned first groove 708 is disposed on a groove bottom of the second groove 709. In this way, the surface of the first electrode 301 away from the base substrate 200 forms a step surface 713 with a stepped shape at the outer periphery of the first groove 708. The step surface 713 includes the fifth end face 712, the sixth end face 711 and the seventh end face 710 that are described above. The fifth end face 712 is covered by the extension portion 407, and the sixth end face 711 and the seventh end face 710 are not covered by the extension portion 407 but covered by the electrode protection portion 505. A groove depth of the second groove 709 is H5, which is a dimension distanced from the fifth end face 712 to the seventh end face 710 in a direction perpendicular to the base substrate 200. A groove depth of the first groove 708 is H6, and in this example, the groove depth H5 of the second groove 709 is greater than the groove depth H6 of the first groove 708.

FIG. 30 is a schematic diagram of a display substrate according to another exemplary embodiment of the present example. In some exemplary embodiments, as shown in FIG. 30, the display substrate does not have a protection layer, that is, the first electrode 301, the partition wall 400, and the base substrate 200 are not covered with a protection layer, and the process of preparing the protection layer is also omitted in the preparation method.

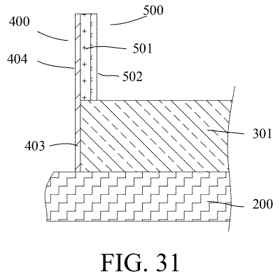

FIG. 31 is a schematic diagram of a display substrate according to yet another exemplary embodiment of the present example. In some exemplary embodiments, as shown in FIG. 31, the partition wall 400 may include a first partition portion 403 and a second partition portion 404 in a direction perpendicular to the base substrate 100, and the connection position of the first partition portion 403 and the second partition portion 404 may be located at the surface of the first electrode 301 away from the base substrate 200, and the first partition portion 403 is bonded to the first electrode 301. The display substrate further includes a protection layer 500, and the protection layer 500 may cover only a surface of the second partition portion 404 close to the first electrode 301. The protection layer 500 may include a first protection layer 501 and a second protection layer 502 that are stacked. The first protection layer 501 is deposited on the partition wall 400, and the second protection layer 502 is deposited on a side of the first protection layer 501 away from the partition wall 400. Both the first protection layer 501 and the second protection layer 502 may adopt an inorganic material layer, and in this example, the material of the first protection layer 501 may be silicon oxide (SiOx), and the material of the second protection layer 502 may be silicon nitride (SiNx). In addition, in order to completely cover the surface of the second partition portion 404 close to the first electrode 301, the protection layer 500 on the second partition portion 404 extends to the first electrode 301 and shields a small portion of an edge of the surface of the first electrode 301 away from the base substrate 200.

In some exemplary embodiments, as shown in FIG. 22, the protection layer pattern may include at least a substrate protection portion 507, a partition protection portion 506 and an electrode protection portion 505. The substrate protection portion 507 covers the base substrate 200 between two adjacent partition walls 400, the partition protection portion 506 covers the partition wall, and the electrode protection portion 505 covers a portion of the surface of the first electrode 301. The electrode protection portion 505 has a pixel opening 303 to expose the surface of the first electrode 301 away from the base substrate 200.

In the process of etching the second photoresist pattern, a portion of the second protection thin film 504 corresponding to the unexposed region 100D as shown in FIG. 21 is first etched and removed to form a second opening 509 as shown in FIG. 26. A portion of the first protection thin film 503 corresponding to the unexposed region 100D as shown in FIG. 21 is then etched and removed to form a first opening 508 as shown in FIG. 26. The second opening 509 and the first opening 508 are in communication with each other and form the pixel opening 303, so as to complete the preparation of the protection layer 500. Since the materials of the second protection thin film 504 and the first protection thin film 503 are different, there is a difference in hardness and etching effect. The opening sizes of the first opening 508 and the second opening 509 formed in the etching process are different, and the opening size of the first opening 508 is less than the opening size of the second opening 509, so that the inner side wall of the pixel opening 303 forms the stepped surface 800. In addition, in the process of forming the first opening 508 by etching, a portion of the transparent conductive layer 705 is etched so that one side of the transparent conductive layer 705 away from the base substrate 200 forms the first groove 708, and an orthographic projection of the first groove 708 on the base substrate 200 overlaps with an orthographic projection of the first opening 508 on the base substrate 200.

Then, the remaining photoresist 100 is stripped off to complete this patterning process, as shown in FIG. 22.

### (4) Forming an Organic Light Emitting Layer.

An organic light emitting layer 305 is formed on the base substrate on which the above-mentioned protection layer pattern is formed, and as shown in FIG. 6, the organic light emitting layer 305 is connected to the first electrode 301 through the pixel opening 303, thereby realizing the connection between the organic light emitting layer 305 and the first electrode 301. The organic light emitting layer 305 is also formed in the first gap 401. The organic light emitting layer 305 in the regions of the pixel opening 303 and the first gap 401 is cut off by the partition wall 400, so that the charge generation layer in the organic light emitting layer 305 can be laterally cut off, the current activity in the lateral direction is reduced, and the purpose of lateral leakage cutoff is achieved.

In some exemplary embodiments, the organic light emitting layer 305 may include a plurality of light emitting film layers (not shown in the figure) stacked in a direction perpendicular to the base substrate 200, and a charge generation layer (not shown in the figure) is disposed between adjacent light emitting film layers. In the preparation process of the organic light emitting layer 305, the light emitting film layer and the charge generation layer are sequentially evaporated. Especially in the evaporation process of the charge generation layer (not shown in the figure), since the height of the partition wall 400 is relatively high, the charge generation layer (not shown in the figure) is laterally cut off at the partition wall 400 as much as possible, so as to achieve the purpose of lateral leakage cutoff (LLC) by the partition wall 400.

### (5) Forming a Second Electrode.

A conductive thin film is evaporated or deposited on the organic light emitting layer 305 to form the second electrode 306. As shown in FIG. 6, the second electrode 306 has a whole-surface structure formed on the organic light emitting layer 305, and the second electrode 306 is connected to the organic light emitting layer 305 so that the organic light emitting layer 305 can emit light under driving of the first electrode 301 and the second electrode 306.

In some exemplary embodiments, the protection layer 500 is deposited in the first gap 401, and the height in the first gap 401 can be appropriately increased to prevent the second electrode 306 from being broken during the formation process.

In some exemplary embodiments, the second electrode 306 may be a cathode, and the second electrode 306 may adopt any one or more of magnesium (Mg), silver (Ag), aluminum (Al), copper (Cu), and lithium (Li), or an alloy made of any one or more of the above metals.

In combination with the above embodiments, the display substrate of the present disclosure realizes the purpose of preventing pixel light crosstalk and partitioning lateral leakage by providing partition walls, and the partition walls occupy a small space for space saving, so that the display substrate can increase the pixel aperture ratio, improve the resolution, and improve the light emitting effect. The first electrode can adopt a multi-layer structure of Ti/TiN/Al/TiN/ITO, which has high reflectivity and work function and improves light emitting efficiency. The space occupied by the partition walls is about 1% to 5% of the space occupied by the existing pixel definition layer structure, which can effectively increase the size of the pixel light emitting region. A part of the inner wall of the partition wall can be bonded to the side wall of the first electrode, which has an excellent protection effect on metals such as aluminum and titanium in the first electrode, and can avoid defects such as aluminum corrosion and cathode puncture. The thickness of the second partition portion is small, and the light emitting area of the pixels in the display region occupied by the partition walls is reduced as much as possible, so as to improve the aperture ratio of the pixels, increase the light emitting area and improve the light emitting efficiency. The thickness of the second partition portion can vary, and gradually decreases from one end connected to the first partition portion to the other end, so that the thickness at one end of the second partition portion away from the first partition portion is thinner, further increasing the light emitting area and improving the light emitting efficiency. The thickness of the first partition portion is thinner than that of the second partition portion, so that the occupied space can be reduced, the pixel density can be increased, and the PPI can be improved. The protection layer covers at least the surface of the partition wall, which can protect the partition wall from being damaged at the thinner partition wall. Since the thickness of the protection portion of the substrate is large, the height in the first gap can be appropriately increased, and defects such as cathode puncture caused by contact between the organic light emitting layer of the evaporation material and the first electrode can be further avoided.

The present disclosure further provides a preparation method for a display substrate for preparing the aforementioned display substrate. In some exemplary embodiments, the preparation method for the display substrate may include: forming a plurality of first electrodes and a plurality of pixel definition structures on a base substrate, wherein at least one of the pixel definition structures includes partition walls disposed outside the first electrodes and surrounding the first electrodes, an orthographic projection of the partition walls on the base substrate does not overlap with an orthographic projection of the first electrodes on the base substrate, each first electrode has a first height, each partition wall has a second height, the second height is greater than the first height, the first height is a maximum distance between a surface of the first electrode away from the base substrate and the base substrate, and the second height is a minimum distance between a surface of the partition wall away from the base substrate and the base substrate; and forming a protection layer on a side of the partition wall and the first electrode away from the base substrate, wherein the protection layer is provided with a pixel opening exposing the first electrode.

In some exemplary embodiments, forming a plurality of first electrodes and a plurality of pixel definition structures on a base substrate may include: forming a composite film layer on the base substrate, coating a photoresist on the composite film layer, and exposing and developing the photoresist to obtain a photoresist pattern; and etching the composite film layer with an etching gas. The etching gas reacts with the photoresist to form polymer particles, the first electrodes are formed after etching the composite film layer, and the polymer particles aggregate to form the partition wall.

The present disclosure also provides a display device which can include the aforementioned display substrate. The display device may be any product or component with a display function, such as a mobile phone, a tablet computer, a television, a display, a laptop computer, a digital photo frame, and a navigator, which is not limited in the embodiments of the present invention.

The above described embodiments are only illustrative of several embodiments of the present disclosure, and the description thereof is more specific and detailed, but the contents described are only embodiments adopted for the convenience of understanding the present disclosure, and are not intended to limit the present disclosure. Any person skilled in the art to which the present disclosure pertains may make any modification and variation in implementation forms and details without departing from the spirit and scope disclosed in the present disclosure. However, the scope of patent protection of the present disclosure is still subject to the scope defined by the appended claims.

1. A display substrate, comprising a base substrate, and a plurality of first electrodes and a plurality of pixel definition structures disposed on the base substrate, wherein the pixel definition structures comprise partition walls;
the partition walls are arranged in one-to-one correspondence with the first electrodes, the partition walls are disposed outside the first electrodes and surround the first electrodes, and adjacent partition walls are spaced apart from each other;
each first electrode has a first height and each partition wall has a second height, and the second height is greater than the first height; and
the first height is configured as a maximum distance between a surface of the first electrode away from the base substrate and a surface of the first electrode close to the base substrate, and the second height is configured as a maximum distance between a surface of the partition wall away from the base substrate and the surface of the first electrode close to the base substrate.

2. The display substrate of claim 1, wherein a material of the partition wall comprises a polymeric material; and
wherein the material of the partition wall comprises a carbon element, an oxygen element, a fluorine element, and a silicon element, and wherein a weight percentage of the oxygen element is from 15% to 40%, and a weight percentage of the carbon element is from 20% to 50%.

3. (canceled)

4. The display substrate of claim 1, wherein a ratio of the second height to the first height is from 1.5 to 4.0.

5. The display substrate of claim 1, wherein the partition wall has a first thickness, a ratio of the second height to the first thickness is configured to be greater than 5, and the first thickness is a maximum thickness of the partition wall in a direction parallel to the base substrate; and
wherein the first thickness is configured to be from 2 nm to 40 nm.

6. (canceled)

7. The display substrate of claim 1, wherein in a direction perpendicular to the base substrate, the partition wall comprises a first partition portion and a second partition portion; one end of the first partition portion is disposed on the base substrate, the other end of the first partition portion is connected to a first end of the second partition portion, and a second end of the second partition portion extends in a direction away from the base substrate; and
the first partition portion is bonded to a side wall of the first electrode.

8. The display substrate of claim 7, wherein the first partition portion has a third height, the second partition portion has a fourth height, and the fourth height is greater than the third height; and
the third height is a dimension of the first partition portion in the direction perpendicular to the base substrate, and the fourth height is a dimension of the second partition portion in the direction perpendicular to the base substrate.

9. The display substrate of claim 7, wherein the first partition portion has a second thickness, the second partition portion has a third thickness, and the second thickness is greater than the third thickness; and
the second thickness is a maximum thickness of the first partition portion in a direction parallel to the base substrate, and the third thickness is a maximum thickness of the second partition portion in the direction parallel to the base substrate; and
wherein a thickness of the second partition portion gradually decreases in the direction away from the base substrate.

10. (canceled)

11. The display substrate of claim 7, wherein the first partition portion has a second thickness, the second partition portion has a third thickness, and the second thickness is less than the third thickness; and
the second thickness is a maximum thickness of the first partition portion in a direction parallel to the base substrate, and the third thickness is a maximum thickness of the second partition portion in the direction parallel to the base substrate; and
wherein a thickness of the first partition portion gradually increases in the direction away from the base substrate.

12. (canceled)

13. The display substrate of claim 1, wherein the pixel definition structures further comprise a protection layer disposed at least on a side of the first electrode away from the base substrate and on the partition wall, and the protection layer is provided with a pixel opening exposing the first electrode.

14. The display substrate of claim 13, wherein the protection layer comprises at least a first protection layer and a second protection layer that are stacked, and materials of the first protection layer and the second protection layer comprise inorganic materials; and
a strain hardening index of the second protection layer is greater than a strain hardening index of the first protection layer, and the strain hardening index of the first protection layer is greater than a strain hardening index of the partition wall.

15. The display substrate of claim 14, wherein the first protection layer has a first refractive index, the second protection layer has a second refractive index, and the partition wall has a third refractive index; and
a ratio of the second refractive index to the first refractive index is from 1.1 to 1.2, and a ratio of the first refractive index to the third refractive index is from 1.1 to 1.2.

16. The display substrate of claim 14, wherein the partition wall has a first thickness, the first protection layer has a fourth thickness, and the second protection layer has a fifth thickness;
a ratio of the fourth thickness to the fifth thickness is from 0.5 to 2, and a ratio of the fourth thickness to the first thickness is from 1 to 10; and
the first thickness is a maximum thickness of the partition wall in a direction parallel to the base substrate, the fourth thickness is an average thickness of the first protection layer in a direction perpendicular to the base substrate, and the fifth thickness is an average thickness of the second protection layer in the direction perpendicular to the base substrate.

17. The display substrate of claim 14, wherein in a direction parallel to the base substrate, the protection layer comprises at least a partition protection portion disposed on a side of the partition wall away from the base substrate and an electrode protection portion disposed on a side of the first electrode away from the base substrate, and the electrode protection portion is provided with the pixel opening exposing the first electrode.

18. The display substrate of claim 17, wherein a sidewall of the pixel opening has a stepped structure.

19. The display substrate of claim 18, wherein the pixel opening comprises a first opening provided on the first protection layer and a second opening provided on the second protection layer; the first opening and the second opening are in communication with each other, and an orthographic projection of the first opening on the base substrate is within a range of an orthographic projection of the second opening on the base substrate.

20. The display substrate of claim 19, wherein the surface of the first electrode away from the base substrate is provided with a first groove, and an orthographic projection of the first groove on the base substrate overlaps with the orthographic projection of the first opening on the base substrate.

21. The display substrate of claim 20, wherein the partition wall further comprises an extension portion located at the surface of the first electrode away from the base substrate, and an orthographic projection of the extension portion on the base substrate overlaps with an orthographic projection of the first electrode on the base substrate;
the surface of the first electrode away from the base substrate comprises a step surface located at an outer periphery of the first groove, and along a direction away from the base substrate, the step surface comprises a seventh end face, a sixth end face, and a fifth end face that are sequentially connected; the fifth end face is located on a side of the seventh end face close to the partition wall, the fifth end face and the seventh end face are both parallel to the base substrate, and the extension portion covers the fifth end face; and
a distance between the fifth end face and the seventh end face in a direction perpendicular to the base substrate is greater than a groove depth of the first groove.

22. A display device, comprising the display substrate of claim 1.

23. A preparation method for a display substrate, comprising:
forming a plurality of first electrodes and a plurality of pixel definition structures on a base substrate, wherein the pixel definition structures comprise partition walls, the partition walls are arranged in one-to-one correspondence with the first electrodes, the partition walls are disposed outside the first electrodes and surround the first electrodes, and adjacent partition walls are spaced apart from each other; each first electrode has a first height, each partition wall has a second height, and the second height is greater than the first height; the first height is configured as a maximum distance between a surface of the first electrode away from the base substrate and a surface of the first electrode close to the base substrate, and the second height is configured as a maximum distance between a surface of the partition wall away from the base substrate and the surface of the first electrode close to the base substrate.

24. The preparation method for a display substrate of claim 23, wherein
forming the plurality of first electrodes and the plurality of pixel definition structures on the base substrate comprises:
forming a composite film layer on the base substrate, coating a photoresist on the composite film layer, and exposing and developing the photoresist to obtain a photoresist pattern; and
etching the composite film layer with an etching gas, wherein the etching gas reacts with the photoresist to form polymer particles, the first electrodes are formed after etching the composite film layer, and the polymer particles aggregate to form the partition walls.
